(19) United States
(12) Patent Application Publication
(10) Pub. No.: US 2008/0017992 A1
(43) Pub. Date: Jan. 24, 2008

(54) Semiconductor device and method of manufacturing the same

(76) Inventors: Masaru Kito, Yokohama-shi (JP); Mitsuru Sato, Yokohama-shi (JP); Yuzo Nagata, Fujisawa-shi (JP); Koji Hashimoto, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/826,224

(22) Filed: Jul. 13, 2007

(30) Foreign Application Priority Data
Jul. 18, 2006 (JP) 2006-195757

(51) Int. Cl. H01L 21/311; H01L 23/48

(52) U.S. Cl. 257/773; 438/696; 257/E21.249; 257/E23.01

(57) ABSTRACT

A first hard mask is formed on a polysilicon film or a target member to be etched, on which a second hard mask composed of amorphous silicon is formed. Ions of boron or the like are implanted into a desired portion of the second hard mask, and then the first hard mask is etched with a mask of the second hard mask. Only the portion not ion-implanted of the second hard mask is etched off by wet etching. A sidewall film is formed on sidewalls of the first hard mask, and then the first hard mask having an upper portion exposed, not covered with the second hard mask is selectively etched off.

### CROSS REFERENCE TO RELATED APPLICATION

This application is based upon and claims the benefit of priority from the prior Japanese Patent Application No. 2006-195757, filed on Jul. 18, 2006, the entire contents of which are incorporated herein by reference.

### BACKGROUND OF THE INVENTION

1. Field of the Invention

The present invention relates to a semiconductor device and method of manufacturing the same. In particular, it relates to a semiconductor device and method of manufacturing the same, of the type that includes etching a target member to be etched through the so-called sidewall transfer process.

2. Description of the Related Art

In formation of a wiring pattern (line-and-space) during a semiconductor manufacturing process, a photolithography mask is used to develop a resist to transfer the pattern to the resist. Then, the resist is used as a mask for etching a target member to be etched in general.

The request for fine patterning semiconductor devices requires formation of a wiring pattern below the resolution limit of lithography and as a method for realizing this formation, the so-called resist slimming process is known (see JP-A 2001-265011, paragraph 0008, FIG. 6, for example). This method comprises developing a resist; and then applying an isotropic etching to the resist or to a sacrifice film and the like etched with a mask of the resist, thereby forming a pattern below the resolution limit of lithography.

As another method, the so-called sidewall transfer process is known. This method comprises forming a hard mask and then a resist on a wiring material; then applying a resist slimming process, and thereafter etching the hard mask using the resist as a mask. After the resist is peeled off, a thin film, which is turned into a sidewall film, is deposited on a sidewall of the hard mask, then an anisotropic etching or the like is used to form the sidewall film on the sidewall of the hard mask. Then, an anisotropic etching or an isotropic etching is applied to selectively remove only the hard mask and leave the. sidewall film. The sidewall film is used as a mask to process the wiring material. This method makes it possible to form a line-and-space having a smaller width than the dimension of the hard mask that is restricted by the resolution limit of lithography.

The sidewall transfer process forms all the wiring patterns as derive from with the sidewall film. Therefore, it can not easily form an arbitrarily sized wire or a pattern having a widened portion at some midpoint of wiring for making a contact. For example, an NAND-type flash memory requires formation of a fine wiring pattern below the resolution limit of lithography in a memory cell array, and formation of a normal wiring pattern based on the resolution of lithography in peripheral circuits and so forth. Therefore, the region in which a fine pattern is formed through the sidewall transfer process and the region in which a transfer is performed based on the resist pattern need individual executions of lithography. For example, U.S. Pat. No. 6,475,891 discloses a technology of forming an arbitrarily sized wire or making a contact. This technology forms such the wire through individual photolithography and accordingly increases the number of process steps, which results in an increase in production cost possibly. In addition, it is difficult to achieve positioning for such the individual photolithography as a problem. As described, there has been no method for simply forming a wiring pattern below the resolution limit of lithography and other arbitrarily sized wiring patterns or contacts, which results in a problem such as an increase in production cost.

### SUMMARY OF THE INVENTION

In an aspect the present invention provides a method of manufacturing semiconductor devices, comprising: forming a first hard mask on a target member to be etched; forming a second hard mask on the first hard mask; implanting ions into a portion of the second hard mask for modification to vary the etch rate for wet etching in comparison with a portion not ion-implanted; etching the first hard mask with a mask of the second hard mask; selectively etching off only the portion not ion-implanted of the second hard mask by wet etching; forming a sidewall film on sidewalls of the first hard mask; selectively etching off the first hard mask having an upper portion exposed, not covered with the second hard mask; and etching off the target member with a mask of the sidewall film and the first hard mask.

In another aspect the present invention provides a method of manufacturing semiconductor devices, comprising: forming a first hard mask on a target member to be etched; forming a second hard mask on the first hard mask; implanting ions into a portion of the second hard mask for modification to vary the etch rate for wet etching in comparison with a portion not ion-implanted; forming a sidewall film on sidewalls of the second hard mask; selectively etching off only the second hard mask not ion-implanted by wet etching; etching the first hard mask with a mask of the second hard mask and the sidewall film; etching off the target member with a mask of the first hard mask.

In one aspect the present invention provides a semiconductor device, comprising a wiring layer, the wiring layer provided by forming a sidewall film in a closed-loop shape along a sidewall of a hard mask, implanting ions into a portion of the hard mask with a mask, then etching off the hard mask except for the portion, and etching a target member to be etched with a mask of the portion and the sidewall film, wherein the wiring layer includes a wider section formed as derived from the portion and the sidewall film, and a wiring section formed as derived only from the sidewall film, wherein the line edge roughness is larger than the line width roughness in the wiring layer, wherein the edge of the wider section and the edge of the wiring section intersect vertical or at an obtuse angle on the inner circumference of the closed-loop shape, wherein the outer circumference of the wiring section along the closed-loop shape is formed in the form of the same straight line, including the proximity of the boundary around the portion.

### BRIEF DESCRIPTION OF THE DRAWINGS

FIG. 1A shows a process step in a method of manufacturing semiconductor devices according to a first embodiment of the present invention.

FIG. 1B shows a process step in the method of manufacturing semiconductor devices according to the first embodiment of the present invention.

FIG. 1C shows a process step in the method of manufacturing semiconductor devices according to the first embodiment of the present invention.

FIG. 1D shows a process step in the method of manufacturing semiconductor devices according to the first embodiment of the present invention.

FIG. 2A shows a process step in the method of manufacturing semiconductor devices according to the first embodiment of the present invention.

FIG. 2B shows a process step in the method of manufacturing semiconductor devices according to the first embodiment of the present invention.

FIG. 2C shows a process step in the method of manufacturing semiconductor devices according to the first embodiment of the present invention.

FIG. 3 shows a process step in the method of manufacturing semiconductor devices according to the first embodiment of the present invention.

FIG. 4 shows a process step in the method of manufacturing semiconductor devices according to the first embodiment of the present invention.

FIG. 5A shows a process step in the method of manufacturing semiconductor devices according to the first embodiment of the present invention.

FIG. 5B shows a process step in the method of manufacturing semiconductor devices according to the first embodiment of the present invention.

FIG. 5C shows a process step in the method of manufacturing semiconductor devices according to the first embodiment of the present invention.

FIG. 6A shows a process step in the method of manufacturing semiconductor devices according to the first embodiment of the present invention.

FIG. 6B shows a process step in the method of manufacturing semiconductor devices according to the first embodiment of the present invention.

FIG. 7 shows a process step in a method of manufacturing semiconductor devices according to a second embodiment of the present invention.

FIG. 8 shows a process step in the method of manufacturing semiconductor devices according to the second embodiment of the present invention.

FIG. 9A shows a process step in the method of manufacturing semiconductor devices according to the second embodiment of the present invention.

FIG. 9B shows a process step in the method of manufacturing semiconductor devices according to the second embodiment of the present invention.

FIG. 9C shows a process step in the method of manufacturing semiconductor devices according to the second embodiment of the present invention.

FIG. 9D shows a process step in the method of manufacturing semiconductor devices according to the second embodiment of the present invention.

FIG. 10 shows a process step in the method of manufacturing semiconductor devices according to the second embodiment of the present invention.

FIG. 11A shows a process step in the method of manufacturing semiconductor devices according to the second embodiment of the present invention.

FIG. 11B shows a process step in the method of manufacturing semiconductor devices according to the second embodiment of the present invention.

FIG. 12A shows a process step in the method of manufacturing semiconductor devices according to the second embodiment of the present invention.

FIG. 12B shows a process step in the method of manufacturing semiconductor devices according to the second embodiment of the present invention.

FIG. 12C shows a process step in the method of manufacturing semiconductor devices according to the second embodiment of the present invention.

FIG. 13A shows a process step in the method of manufacturing semiconductor devices according to the second embodiment of the present invention.

FIG. 13B shows a process step in the method of manufacturing semiconductor devices according to the second embodiment of the present invention.

FIG. 14 shows a process step in a method of manufacturing semiconductor devices according to a third embodiment of the present invention.

FIG. 15 shows a process step in the method of manufacturing semiconductor devices according to the third embodiment of the present invention.

FIG. 16 shows a process step in the method of manufacturing semiconductor devices according to the third embodiment of the present invention.

FIG. 17A shows a process step in the method of manufacturing semiconductor devices according to the third embodiment of the present invention.

FIG. 17B shows a process step in the method of manufacturing semiconductor devices according to the third embodiment of the present invention.

FIG. 18A shows a process step in the method of manufacturing semiconductor devices according to the third embodiment of the present invention.

FIG. 18B shows a process step in the method of manufacturing semiconductor devices according to the third embodiment of the present invention.

FIG. 18C shows a process step in the method of manufacturing semiconductor devices according to the third embodiment of the present invention.

FIG. 19A shows a process step in the method of manufacturing semiconductor devices according to the third embodiment of the present invention.

FIG. 19B shows a process step in the method of manufacturing semiconductor devices according to the third embodiment of the present invention.

FIG. 19C shows a process step in the method of manufacturing semiconductor devices according to the third embodiment of the present invention.

FIG. 19D shows a process step in the method of manufacturing semiconductor devices according to the third embodiment of the present invention.

FIG. 20A shows a process step in a method of manufacturing semiconductor devices according to a fourth embodiment of the present invention.

FIG. 20B shows a process step in the method of manufacturing semiconductor devices according to the fourth embodiment of the present invention.

FIG. 20C shows a process step in the method of manufacturing semiconductor devices according to the fourth embodiment of the present invention.

FIG. 21 shows a process step in the method of manufacturing semiconductor devices according to the fourth embodiment of the present invention.

FIG. 22 shows a process step in the method of manufacturing semiconductor devices according to the fourth embodiment of the present invention.

FIG. 23 shows a process step in the method of manufacturing semiconductor devices according to the fourth embodiment of the present invention.

FIG. 24 shows a process step in the method of manufacturing semiconductor devices according to the fourth embodiment of the present invention.

FIG. 25A shows a process step in the method of manufacturing semiconductor devices according to the fourth embodiment of the present invention.

FIG. 25B shows a process step in the method of manufacturing semiconductor devices according to the fourth embodiment of the present invention.

FIG. 25C shows a process step in the method of manufacturing semiconductor devices according to the fourth embodiment of the present invention.

FIG. 26 is a process diagram illustrative of the concept of the method of manufacturing semiconductor devices according to the embodiment of the present invention.

FIG. 27 is a process diagram illustrative of the concept of the method of manufacturing semiconductor devices according to the embodiment of the present invention.

FIG. 28 is a process diagram illustrative of the concept of the method of manufacturing semiconductor devices according to the embodiment of the present invention.

FIG. 29 is a process diagram illustrative of the concept of the method of manufacturing semiconductor devices according to the embodiment of the present invention.

FIG. 30 is a process diagram illustrative of the concept of the method of manufacturing semiconductor devices according to the embodiment of the present invention.

FIG. 31 is a process diagram illustrative of the concept of the method of manufacturing semiconductor devices according to the embodiment of the present invention.

FIG. 32 is a process diagram illustrative of the concept of the method of manufacturing semiconductor devices according to the embodiment of the present invention.

FIG. 33 is a process diagram illustrative of the concept of the method of manufacturing semiconductor devices according to the embodiment of the present invention.

FIG. 34 is a process diagram illustrative of the concept of the method of manufacturing semiconductor devices according to the embodiment of the present invention.

FIG. 35 is a process diagram illustrative of the concept of the method of manufacturing semiconductor devices according to the embodiment of the present invention.

### DETAILED DESCRIPTION OF THE EMBODIMENTS

The embodiments of the present invention will now be described in detail with reference to the drawings.

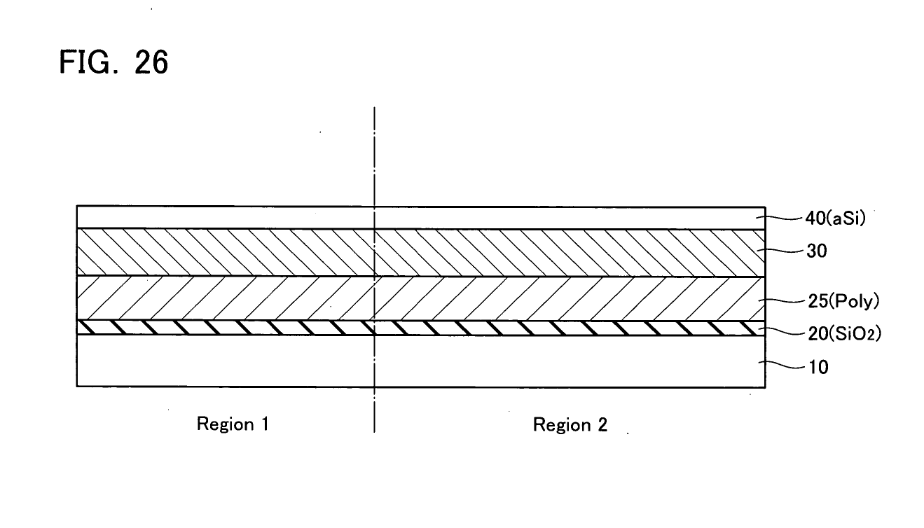

Prior to the description of the specified embodiments, the concept of the embodiment of the present invention is described with reference to process diagrams of FIGS. 26-35. In an example, an etching is applied to a target member to be etched or a polysilicon film 25 formed on a semiconductor substrate 10 with a silicon oxide film 20 interposed therebetween. In addition, the sidewall transfer process is used to form wiring patterns of the polysilicon film 25 below the resolution limit of lithography in a region 1 (FIG. 26), and other wiring patterns of any width of the polysilicon film 25 in a region 2 at the same time.

First, as shown in FIG. 26, a first hard mask 30 is deposited on the target member or the polysilicon film 25 for use in etching the film. Further, a second hard mask 40 is formed on the first hard mask 30. The second hard mask 40 is composed of a material having the property of providing an etching rate for wet etching variable with ion implantation, such as amorphous silicon and polysilicon. The second hard mask 40 is formed to etch the first hard mask 30 in a desired pattern.

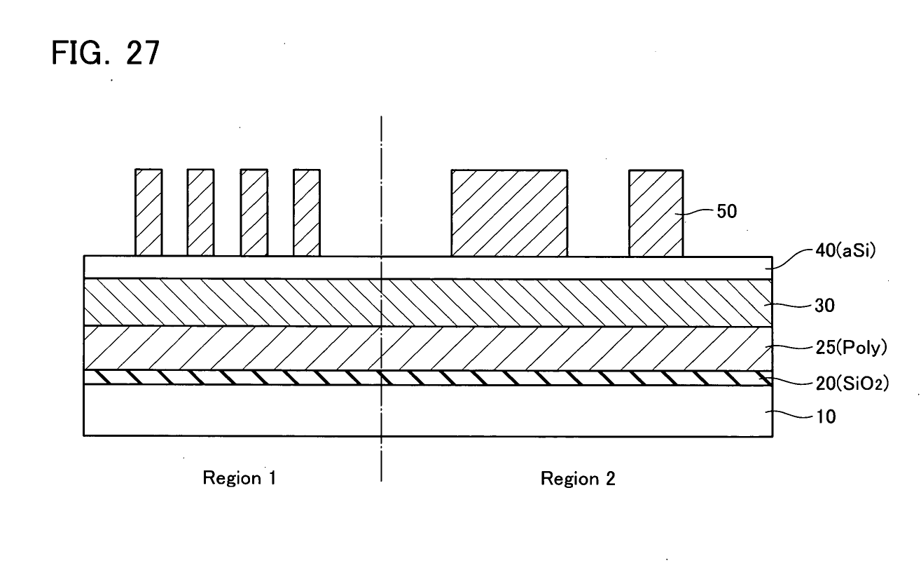

Next, as shown in FIG. 27, a resist is applied over the entire surface of the second hard mask 40, and then a process of photolithography is used to develop the resist in a desired pattern to form the resist 50 having a desired pattern shape. In an example, the resist 50 in the region 1 has a line-and-space of the minimum line width W that is the resolution limit of lithography, in which lines and spaces have almost the same interval W.

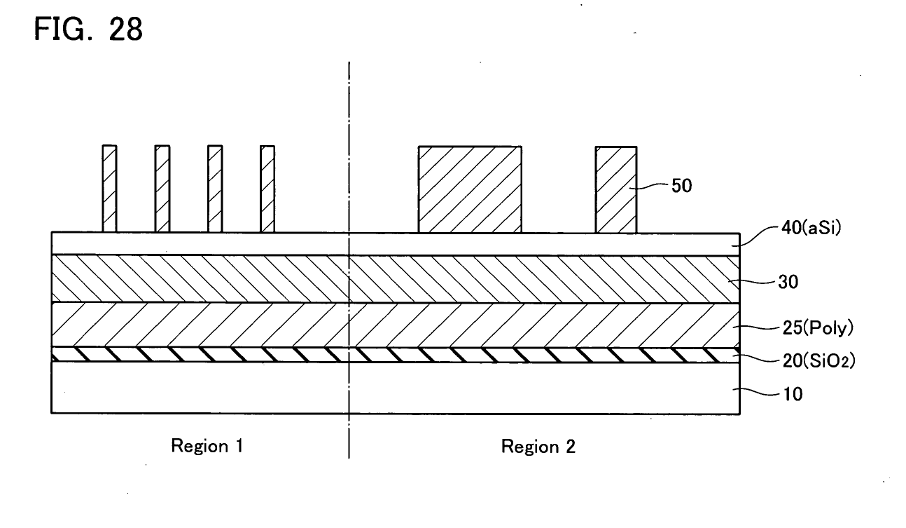

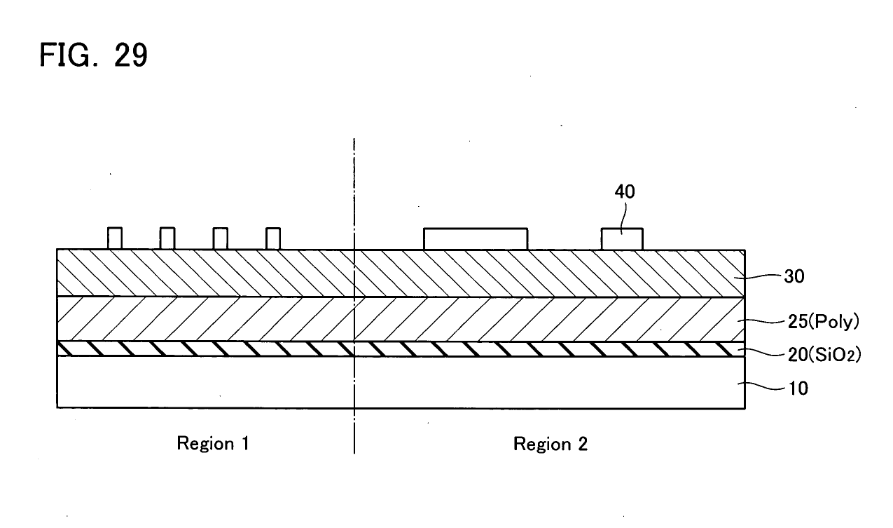

Subsequently, as shown in FIG. 28, the resist 50 is subjected to a slimming process through an isotropic etching, thereby fine patterning the resist 50 to a width below the resolution limit of lithography. Then, as shown in FIG. 29, an anisotropic etching with a mask of the slimmed resist 50 is applied to etch the second hard mask 40. After the etching, the resist 50 is peeled off.

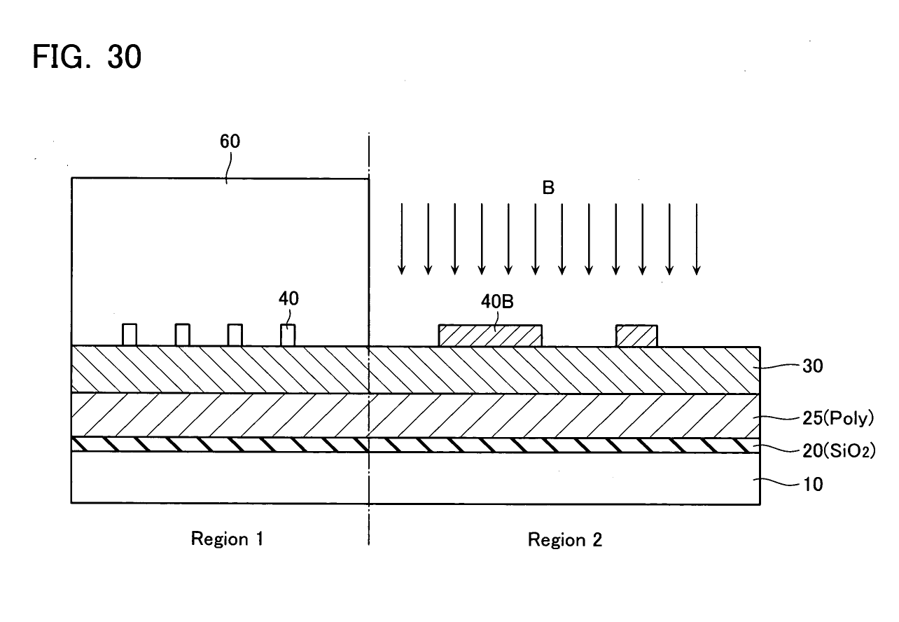

Then, as shown in FIG. 30, a resist 60 is formed only over a region of the second hard mask 40 (the region 1 in this example), which is intended to form a line-and-space pattern therein below the resolution limit of lithography through the sidewall transfer process. With a mask of the resist 60, ions of an impurity (preferably, boron (B), phosphorous (P), arsenic (As) or boron difluoride (BF₂)) are implanted into the second hard mask 40. As a result, the second hard mask 40B ion-implanted, which is not covered with the resist 60, is given a lower etch rate for wet etching with an alkaline solution, in comparison with the second hard mask 40 not ion-implanted, which is covered with the resist 60.

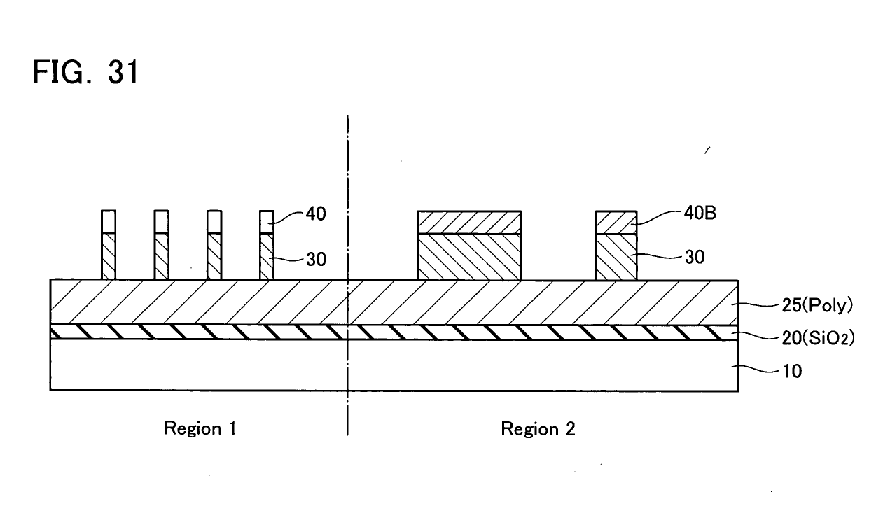

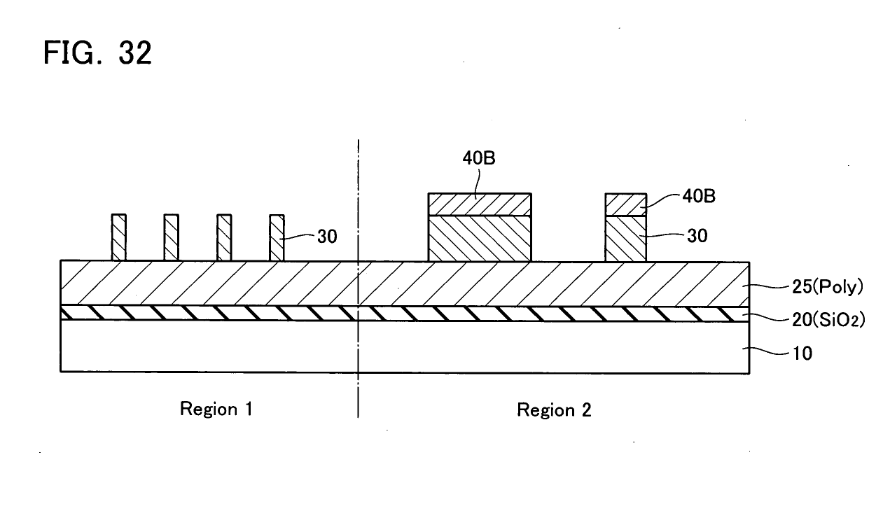

Subsequently, after peeling off the resist 60, as shown in FIG. 31, an anisotropic etching with a mask of the second hard masks 40, 40B is applied to etch the first hard mask 30. Thereafter, as shown in FIG. 32, a wet etching with an alkaline solution is used to selectively remove the second hard mask 40 not ion-implanted and leave the second hard mask 40B ion-implanted.

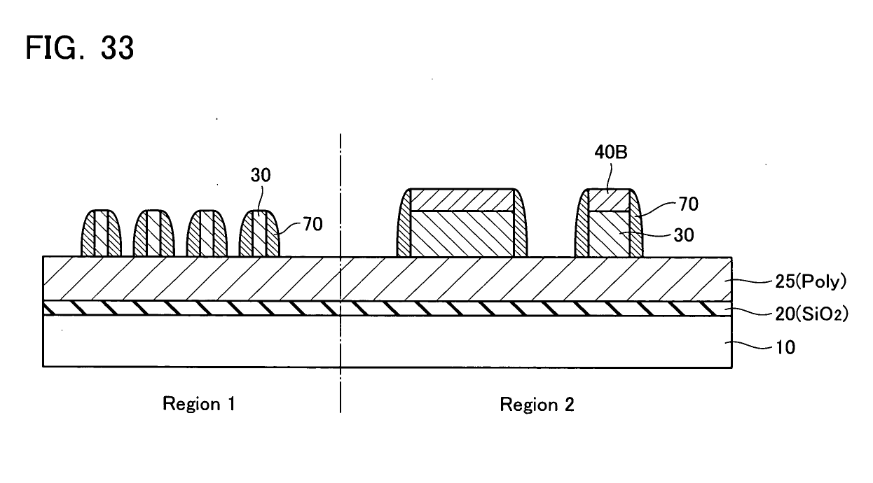

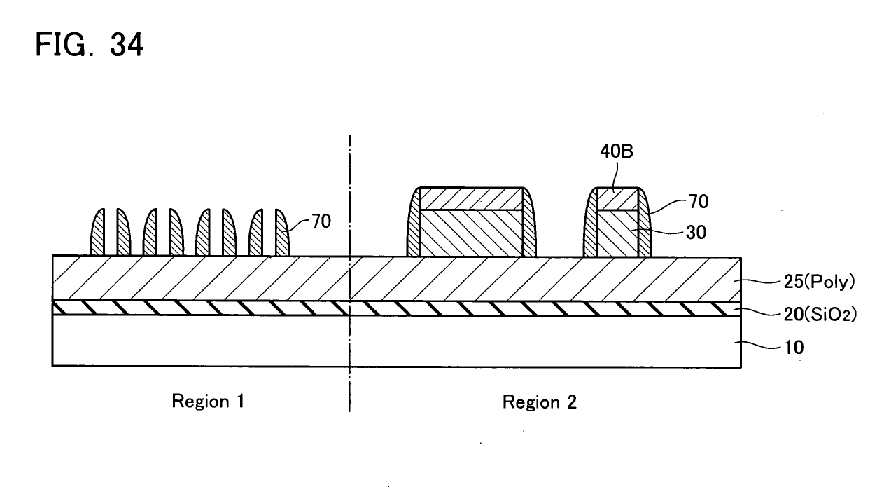

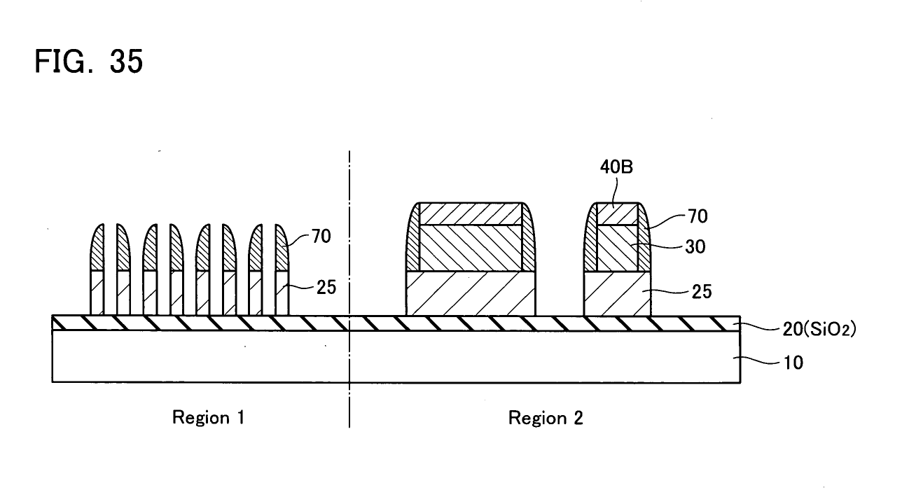

Thereafter, over the entire surface of the first hard mask 30 including the upper surface and sidewalls, a sidewall material film is deposited through a CVD process or the like. Then, an anisotropic etching is applied to etch the sidewall material film to leave it only on sidewalls of the first hard mask 30 and the second hard mask 40B left. The film left is turned into a sidewall film 70 as shown in FIG. 33. Subsequently, a wet etching is employed to etch off the first hard mask 30, as shown in FIG. 34, which is sandwiched between portions of the sidewall film 70 and has an upper portion exposed in the region 1. On the other hand, the first hard mask 30 covered with the second hard mask 40B in the region 2 is left because it is not etched. As a result, only the sidewall film 70 remains in the region 1. As shown in FIG. 35, by etching with a mask of the sidewall film 70, the target member or the polysilicon film 25 is etched to form a wiring pattern below the resolution limit of lithography in the region 1. On the other hand, the first hard mask 30 is left in the region 2 because it is not etched. This first hard mask 30 together with the sidewall film 70 serves as a etching mask. Therefore, wiring patterns of any width and contact fringe regions can be formed in the region 2 in the same process steps as those for forming the wiring pattern through the sidewall transfer process in the memory cell array region (the wiring pattern below the resolution limit of lithography).

### FIRST EMBODIMENT

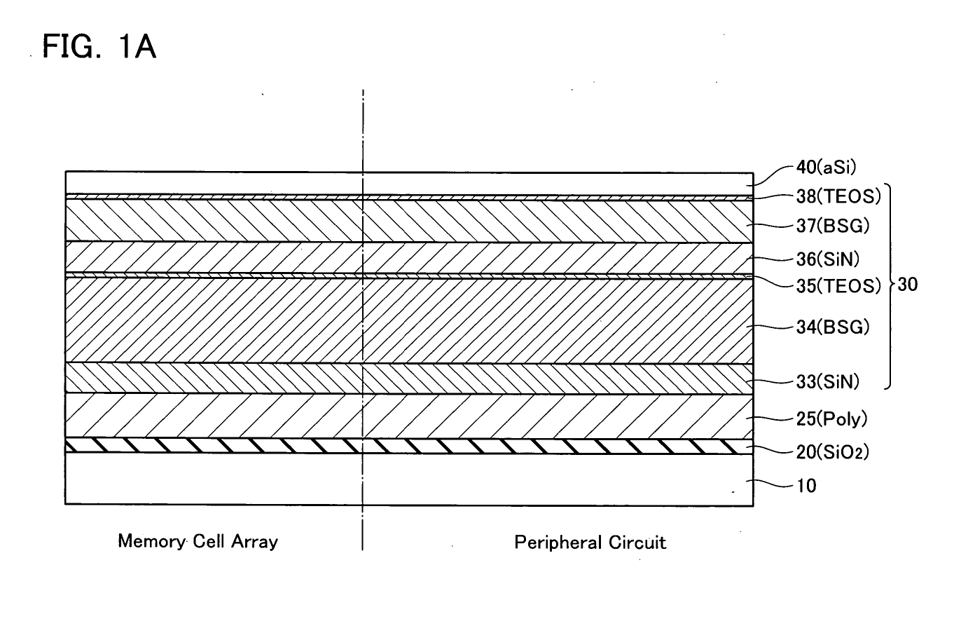

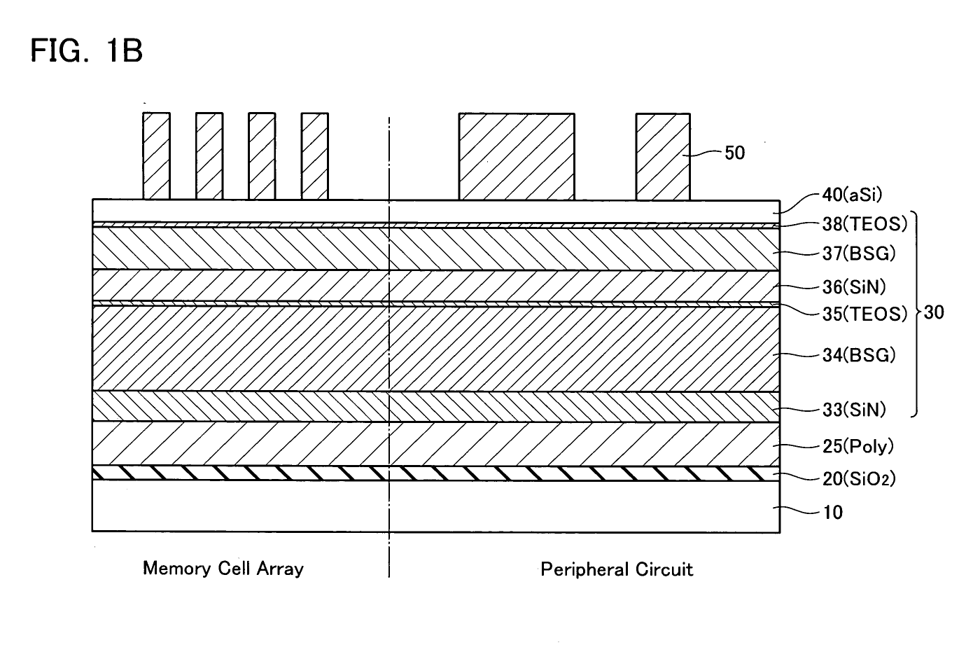

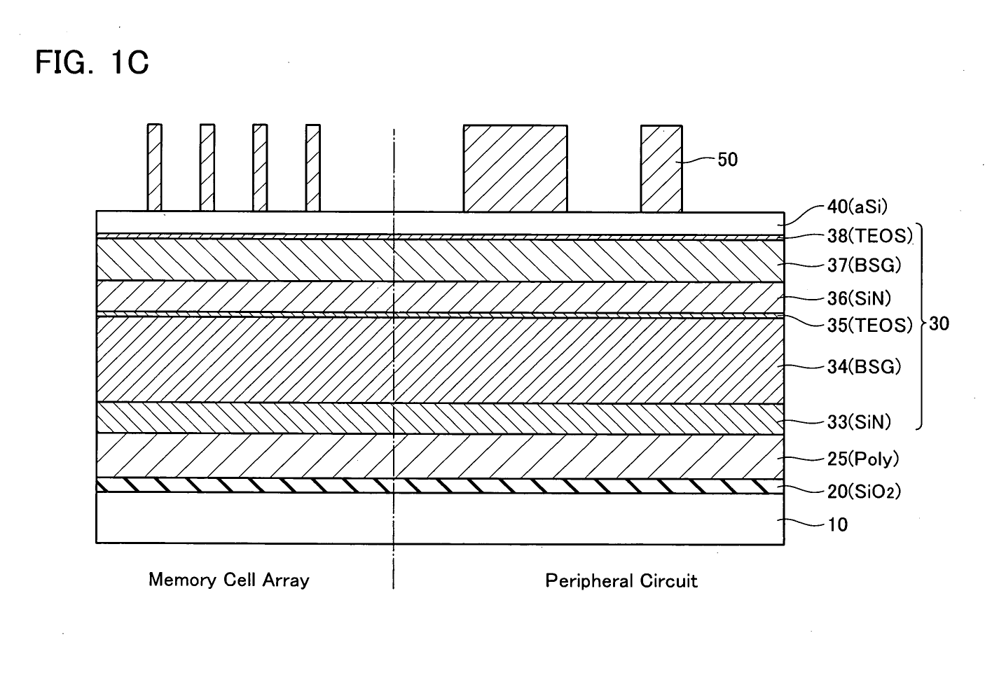

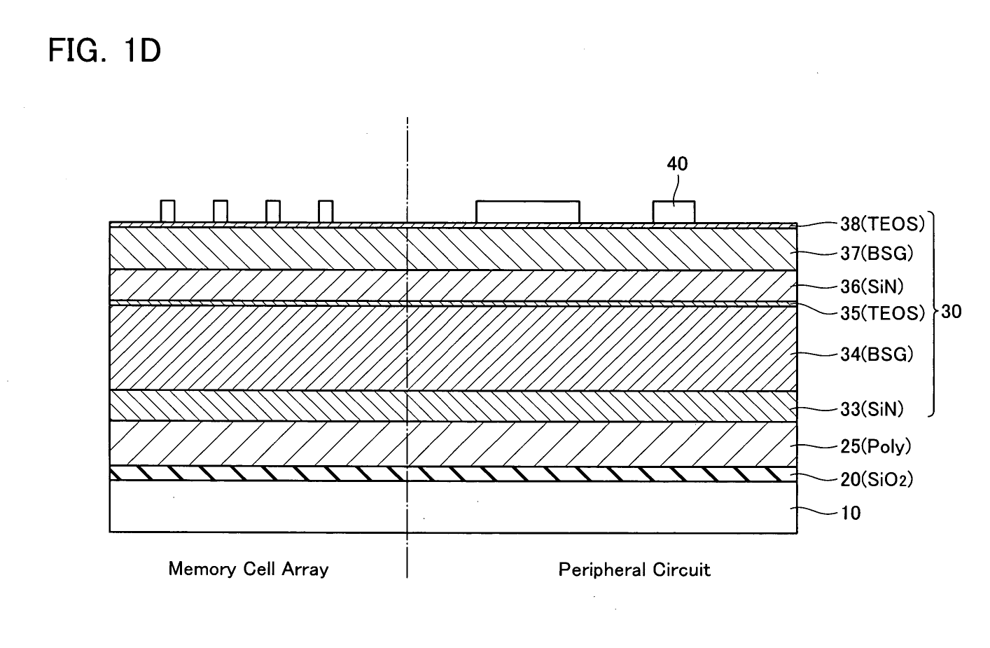

A method of manufacturing semiconductor devices according to a first embodiment of the present invention is described with reference to FIGS. 1A-6B. In the following example, a polysilicon film 25 formed on a semiconductor substrate 10 with a silicon oxide film 20 interposed therebetween is etched as a target member. In addition, the sidewall transfer process is used to form wiring patterns of the polysilicon film 25 below the resolution limit of lithography in the memory cell array region, and other wiring patterns of any width or contact fringe regions of the polysilicon film 25 in peripheral circuit portions at the same time.

First, as shown in FIG. 1A, a first hardmask 30 is deposited on the target member or the polysilicon film 25 for use in etching the film. The first hard mask 30 in this example is formed of a silicon nitride film (SiN) 33, a BSG film 34, a TEOS film 35, a silicon nitride film 36, a BSG film 37, and a TEOS film 38, deposited from below. This is an example to the last and various types (the number of layers, thicknesses of layers, materials and so forth) may be employed in consideration of the etching condition and the mask material.

Of the first hard mask 30, the BSG film 37 and the TEOS film 38 serve as a sidewall formation film for forming a sidewall film as described later. Further, a second hard mask 40 composed of amorphous silicon is formed on the first hard mask 30. The second hard mask 40 is formed to etch the first hard mask 30 including the BSG film 37 and the TEOS film 38 (sidewall formation film) in a desired pattern. The sidewall formation film herein includes the BSG film 37 and the TEOS film 38 though the present invention is not limited to this example but rather can be modified variously within a range that exerts the same effect. Instead of amorphous silicon, the second hard mask 40 may be composed of a material having the property of providing an etching rate for wet etching variable with ion implantation, such as polysilicon, to form the sidewall film 70. This is also same as in the following embodiments.

Next, as shown in FIG. 1B, an anti reflective film (not shown) and a resist are applied over the entire surface of the second hard mask 40. Thereafter, a process of photolithography is used to develop the resist in a desired pattern to form the resist 50 having a desired pattern shape. In this example, the resist 50 in the memory cell array region has a line-and-space of the minimum line width W that is the resolution limit of lithography, in which lines and spaces have almost the same interval W.

Subsequently, as shown in FIG. 1C, an isotropic etching is used to etch the anti reflective film, not shown, and a slimming process is applied to the resist 50 at the same time for fine patterning the resist 50 to a width below the resolution limit of lithography. For example, the memory cell array region is designed herein to have a line width of ½ W and a space width of 3/2 W. The dimension of the resist 50 is also fine-patterned in the peripheral circuit region. Subsequently, as shown in FIG. 1D, the slimmed resist 50 is used as a mask to etch the second hard mask 40 by anisotropic etching. After etching, the resist 50 is peeled off.

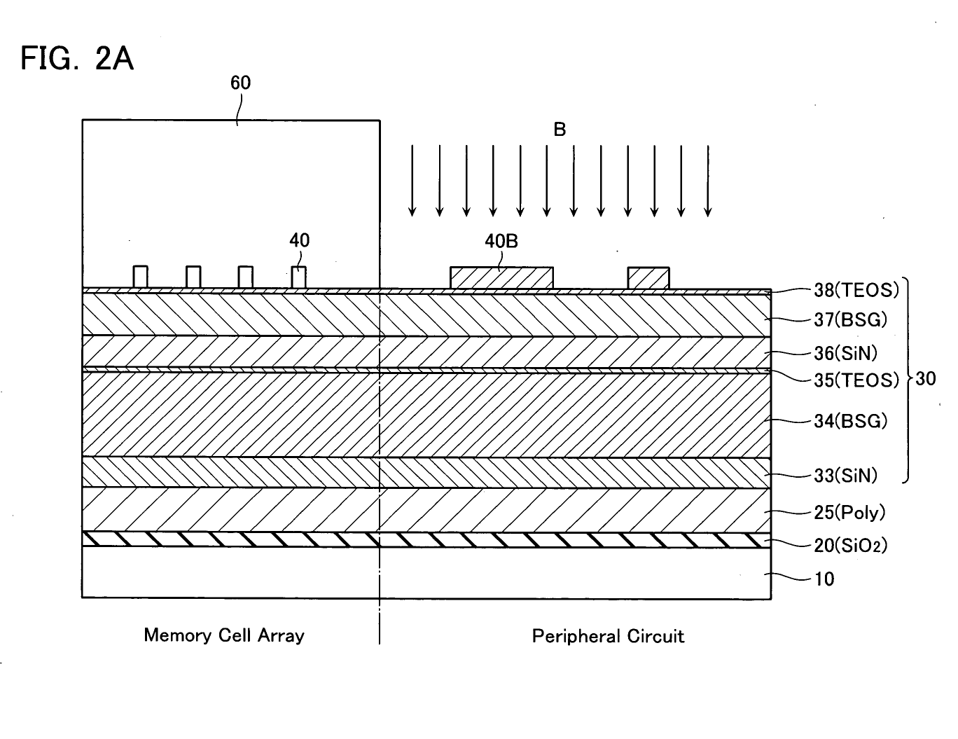

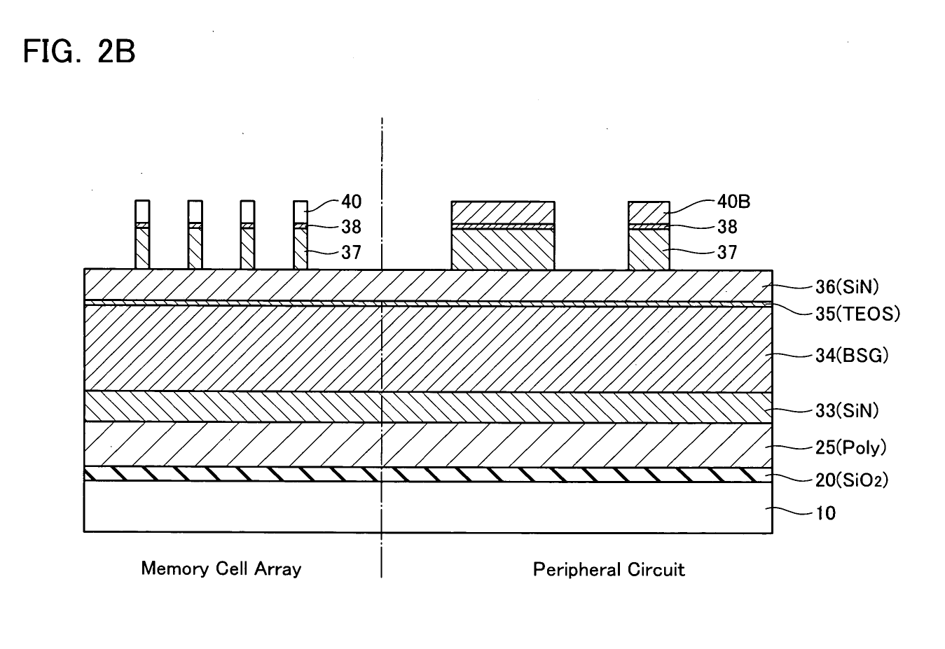

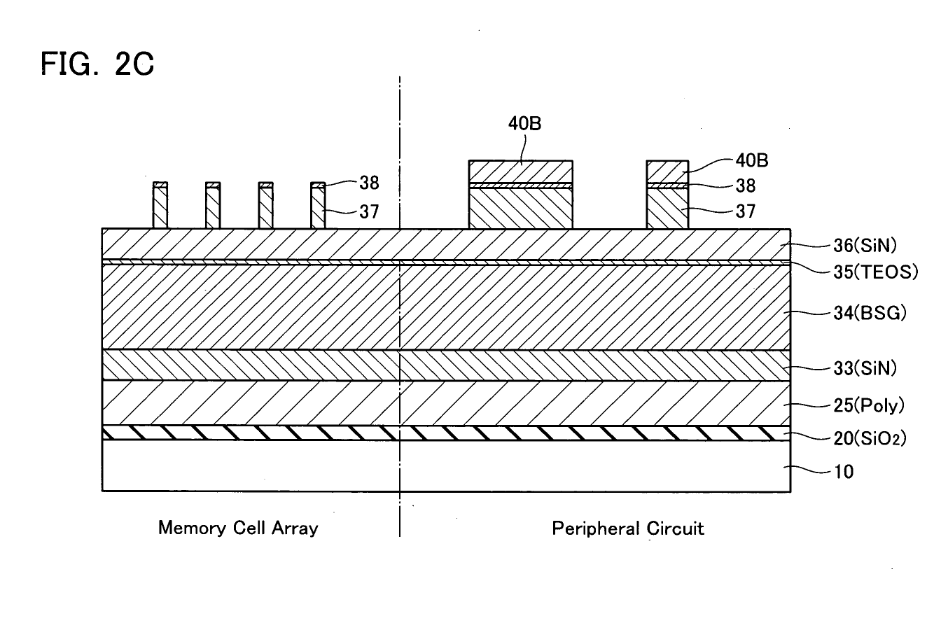

Then, as shown in FIG. 2A, a resist 60 is formed only over a region of the second hard mask 40 (the memory cell array in this example), which is intended to form a line-and-space pattern therein below the resolution limit of lithography through the sidewall transfer process. Using the resist 60 as a mask, ions of an impurity (preferably, boron (B) , phosphorous (P), arsenic (As) or boron difluoride (BF₂)) are implanted into the second hard mask 40. As an example, the ion implantation condition is adjusted such that the hard mask 40B ion-implanted has an impurity concentration of 1×10²⁰ cm⁻³. As a result, the second hard mask 40B ion-implanted, which is not covered with the resist 60, is given a lower etch rate for wet etching with an alkaline solution, in comparison with the second hard mask 40 not ion-implanted, which is covered with the resist 60.

Subsequently, after peeling off the resist 60, as shown in FIG. 2B, an anisotropic etching with a mask of the second hard masks 40, 40B is applied to etch the sidewall formation film, or the TEOS film 38 and the BSG film 37, of the first hard mask 30. Thereafter, as shown in FIG. 2C, a wet etching with an alkaline solution is used to selectively remove the second hard mask 40 not ion-implanted and leave the second hard mask 40B ion-implanted. The wet etching with an alkaline solution has a high selective ratio for the oxide film and the nitride film. Accordingly, it has no ill effect at all on the sidewall formation film, or the TEOS film 38 and the BSG film 37, and the underlying layer, or the silicon nitride film 36. This method can easily remove only the second hard mask 40 in the memory cell array without having any side effect on others.

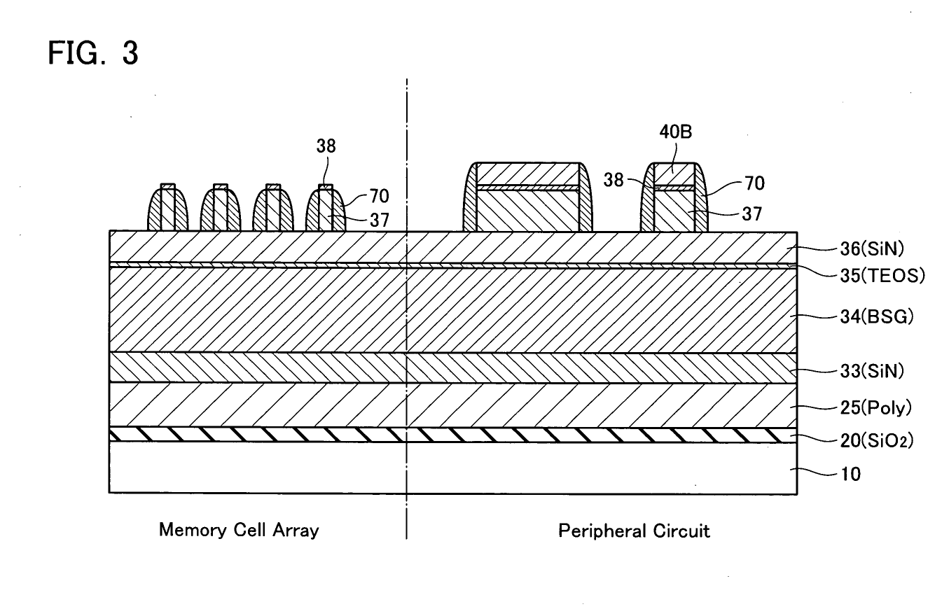

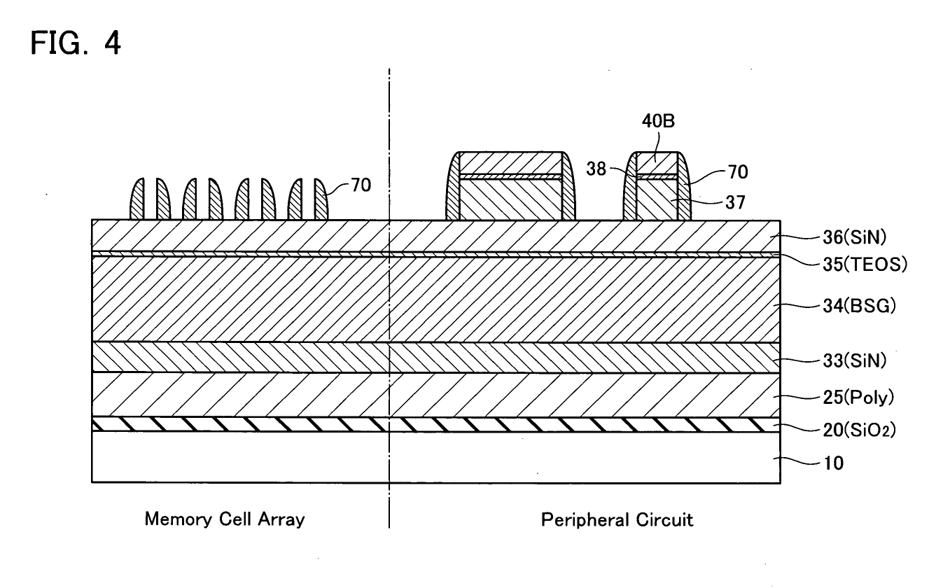

Thereafter, over the entire surface of the first hard mask 30, including sidewalls of the TEOS film 38 and the BSG film 37 etched and the upper surface of the second hard mask 40, an amorphous silicon film is deposited through a CVD process. Then, an anisotropic etching is applied to etch the amorphous silicon film to leave it only on sidewalls of the TEOS film 38 and the BSG film 37 and sidewalls of the second hard mask 40B. The film left is turned into a sidewall film 70 (amorphous silicon film) as shown in FIG. 3. Preferably, the sidewall film 70 reaches the sidewall of the second hard mask 40B to prevent the TEOS film 38 and the BSG film 37 from being etched in the next step (FIG. 4).

In the memory cell array region, the TEOS film 38 and the BSG film 37 are etched to a width of around ½ W, a half the minimum line width W in accordance with the resolution limit. Therefore, the thickness of the deposited amorphous silicon and the etching condition are herein set such that the sidewall film 70 has a width of around ½ W.

Subsequently, a wet etching with a dilute HF or the like is employed to etch off the TEOS film 38 and the BSG film 37, as shown in FIG. 4, which are sandwiched between portions of the sidewall film 70, having an upper portion exposed in the memory cell array region. On the other hand, the TEOS film 38 and the BSG film 37 covered with the second hard mask 40B are left in the peripheral circuit region because they are not etched. As a result, in the memory cell array region, only the sidewall film 70 with a width of ½ W remains with a space width of ½ W on the silicon nitride film 36. Etching with a mask of such the sidewall film 70 only can form a wiring pattern with a line width of ½ W and a space width of ½ W below the resolution limit of lithography in the memory cell array region. On the other hand, the TEOS film 38 and the BSG film 37 covered with the second hard mask 40B and the sidewall film 70 are left in the peripheral circuit region because they are not etched. These films serve as an etching mask together with the sidewall film 70. Therefore, setting the resist 50 (FIG. 1C) to have any width allows wiring patterns of any width and contact fringe regions to be formed in the peripheral circuit region in the same steps as those for forming the wiring pattern through the sidewall transfer process in the memory cell array region (the wiring pattern below the resolution limit of lithography).

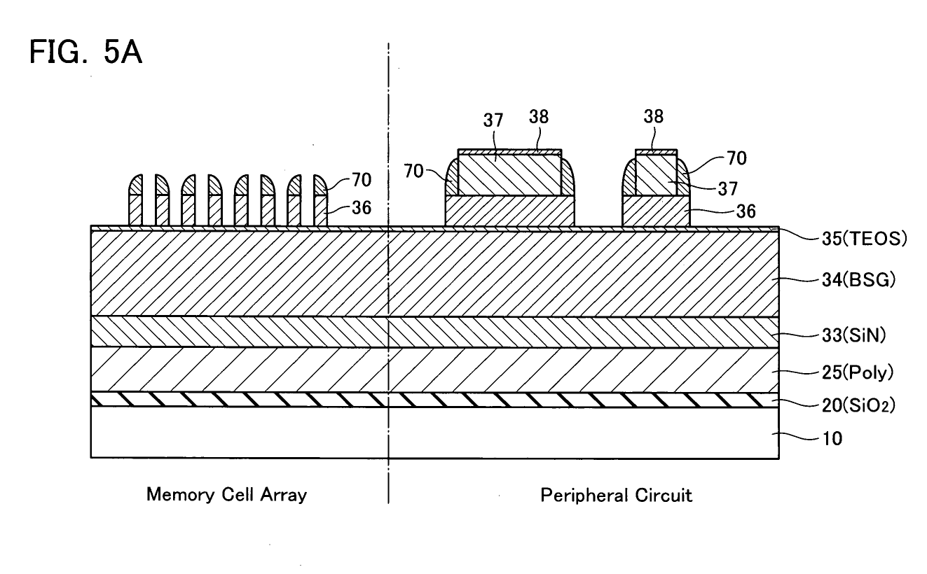

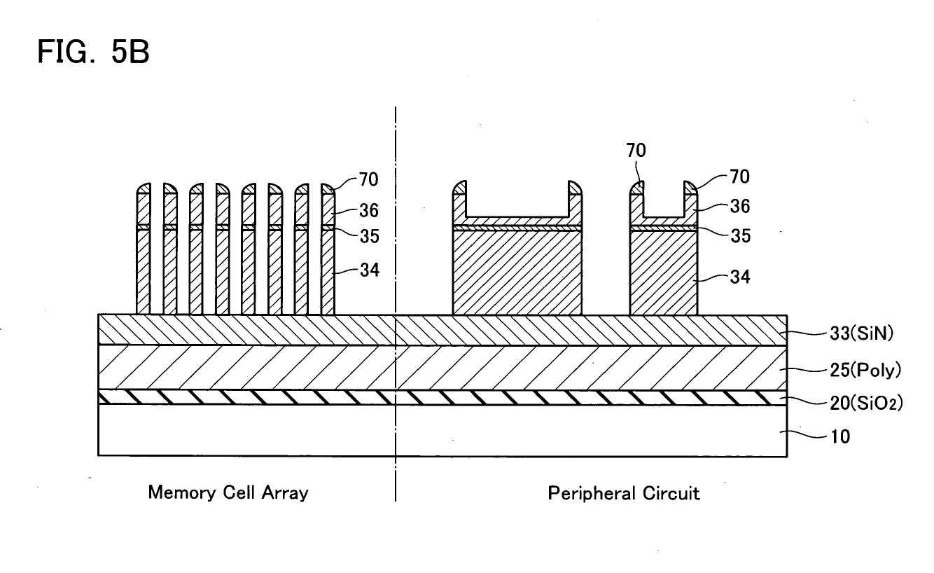

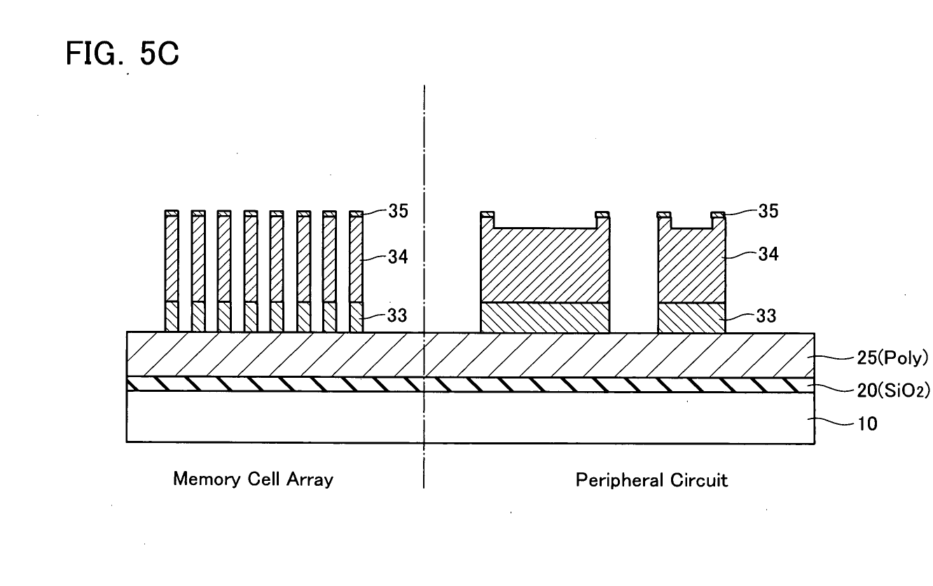

Thereafter, as shown in FIG. 5A, the sidewall film 70 composed of amorphous silicon and the second hard mask 40B similarly composed of amorphous silicon are used as a mask for anisotropic etching to etch the silicon nitride film 36. Preferably, the second hard mask 40B is designed to have such a thickness that enables the second hard mask 40B to be etched off.

Further, the etching is continued with a mask of the sidewall film 70 to etch the TEOS film 35 and the BSG film 34 as shown in FIG. 5B. In the peripheral circuit region, after the second hard mask 40B is removed, the underlying layers of the TEOS film 38, the BSG film 37 and the silicon nitride film 36 are also etched. Preferably, the film thickness and the etching condition are set such that the silicon nitride film 36 can not be etched completely.

Subsequently, as shown in FIG. 5C, the silicon nitride film 33 is etched from above the target member or the polysilicon film 25. At this moment, at least in the peripheral circuit region, the film left as the first hard mask 30 includes only the silicon nitride film 33, the BSG film 34, and the TEOS film 35. It is suitable though to select the etching condition and so forth such as to remove the TEOS film 35 and leave only the BSG film 34 on the silicon nitride film 33.

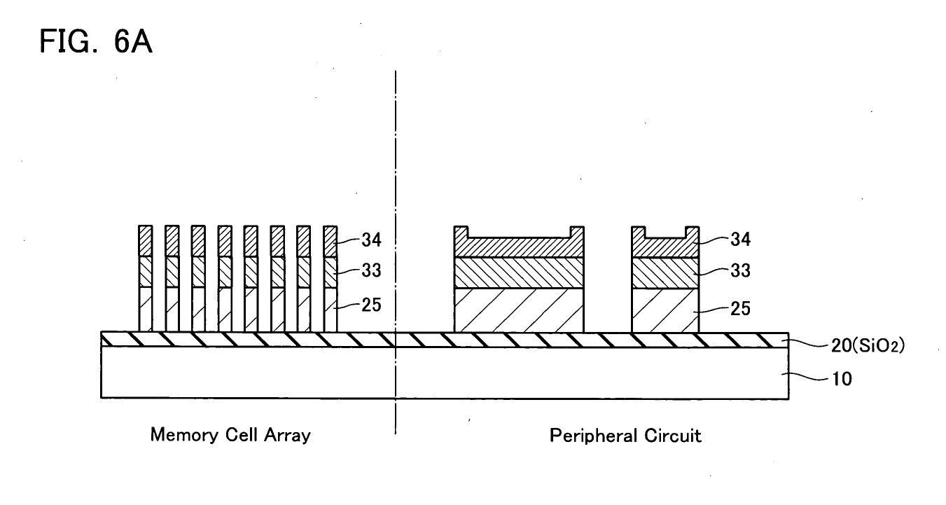

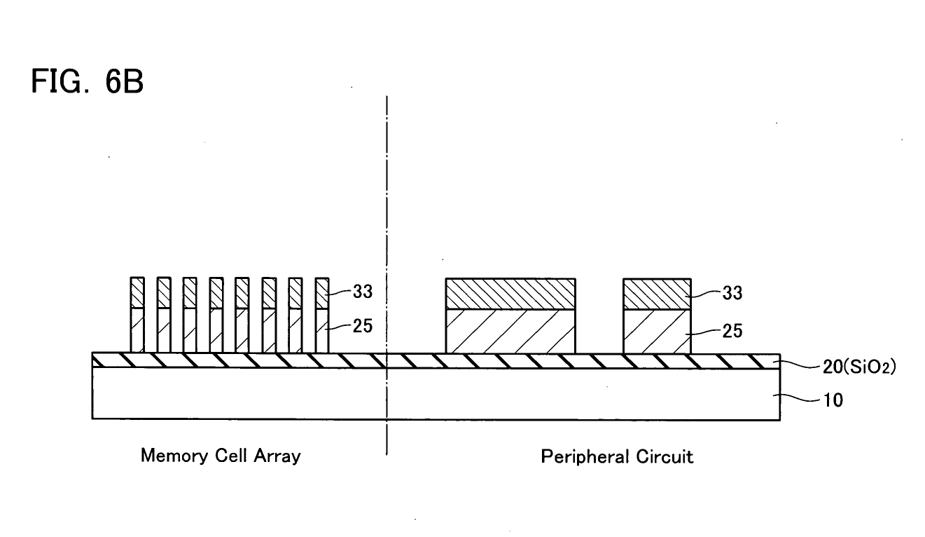

Next, as shown in FIG. 6A, using the BSG film 34 as a mask to etch the target member or the polysilicon film 25. Further, as shown in FIG. 6B, a HF vapor treatment or the like is applied to etch only the BSG film 34 under the condition with a high selective ratio for the silicon oxide 20. As a result, the polysilicon film 25 can be formed with the cap layer of the silicon nitride film 33 thereon.

As described, in the present embodiment, ions of an impurity such as boron are implanted into a desired portion of the second hard mask 40 composed of amorphous silicon, thereby forming wiring patterns below the resolution limit of lithography and other wiring patterns of any width through an identical lithography. This is effective to reduce the difficulty of lithography particularly over the prior art.

### SECOND EMBODIMENT

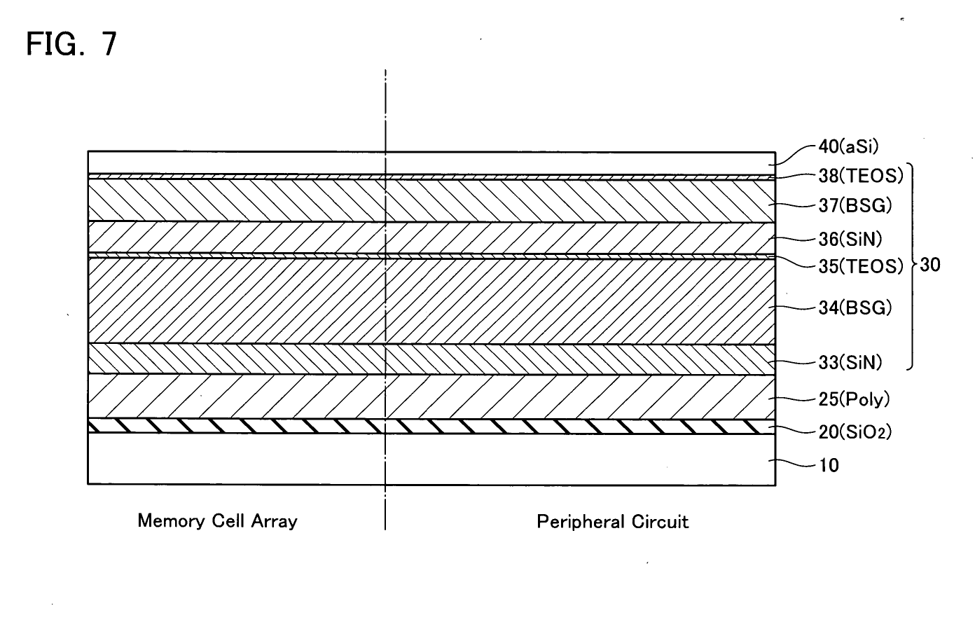

A method of manufacturing semiconductor devices according to a second embodiment of the present invention is described next with reference to FIGS. 7-13B, in which the same components as those in the first embodiment are denoted with the same reference numerals and the duplicated description thereof is omitted hereafter. In the following description, similar to the first embodiment, the polysilicon film 25 formed on the semiconductor substrate 10 with the silicon oxide film 20 interposed therebetween is etched as the target member. In addition, the sidewall transfer process is used to form wiring patterns below the resolution limit of lithography in the memory cell array region, and other wiring patterns of any size or contact fringe regions in the peripheral circuit portion at the same time.

First, as shown in FIG. 7, a first hard mask 30 is deposited on the polysilicon film 25. The first hard mask 30 is composed of a silicon nitride film (SiN) 33, a BSG film 34, a TEOS film 35, a silicon nitride film 36, a BSG film 37, and a TEOS film 38, deposited from below, similar to the first embodiment. Further, a second hard mask 40 composed of amorphous silicon is deposited on the first hard mask 30. The second hard mask 40 may be a deposition of polysilicon.

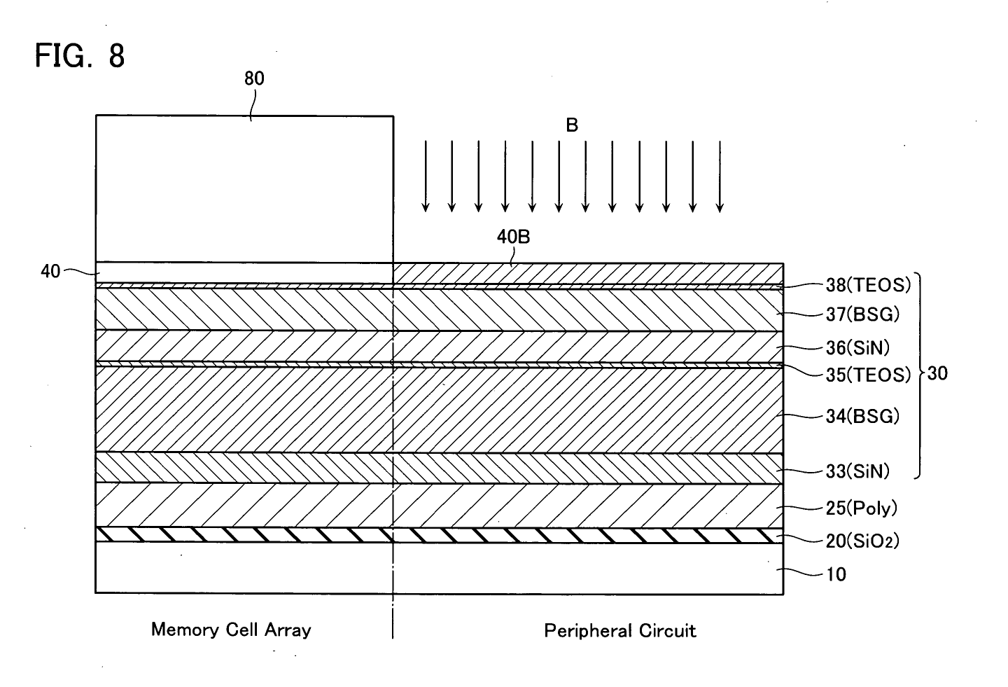

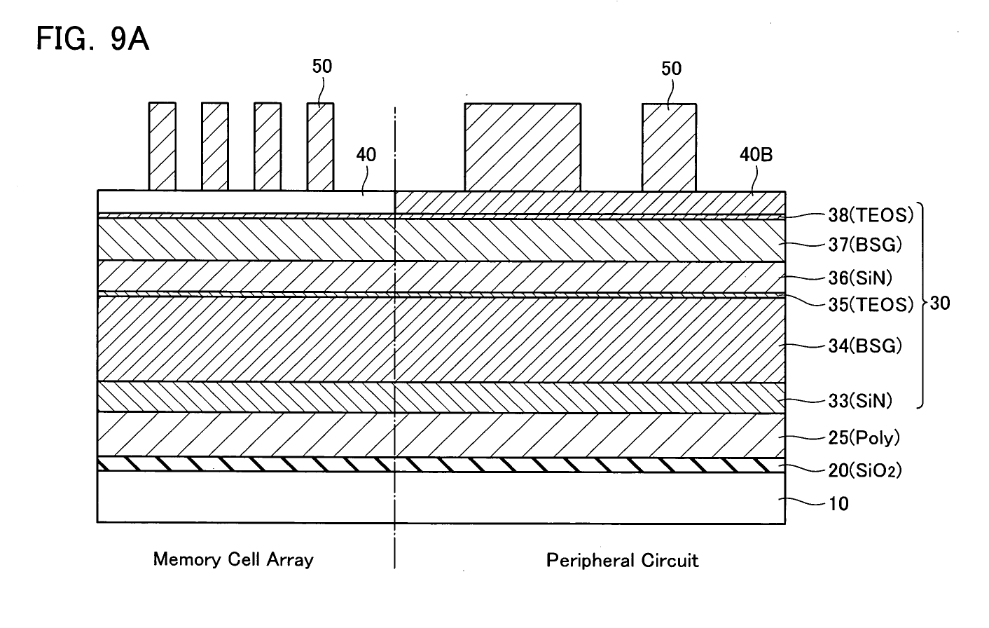

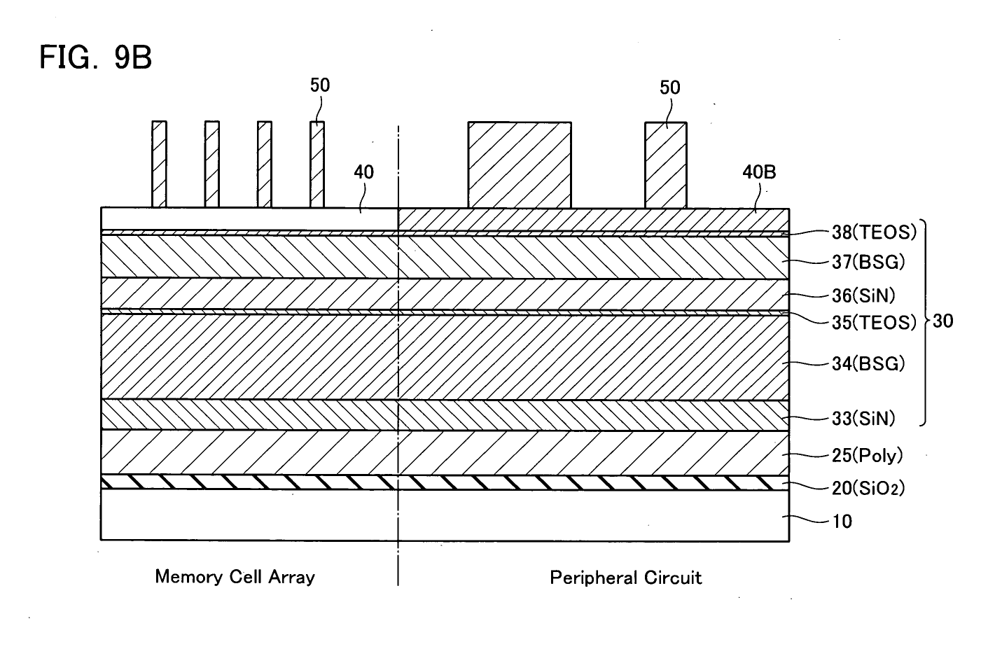

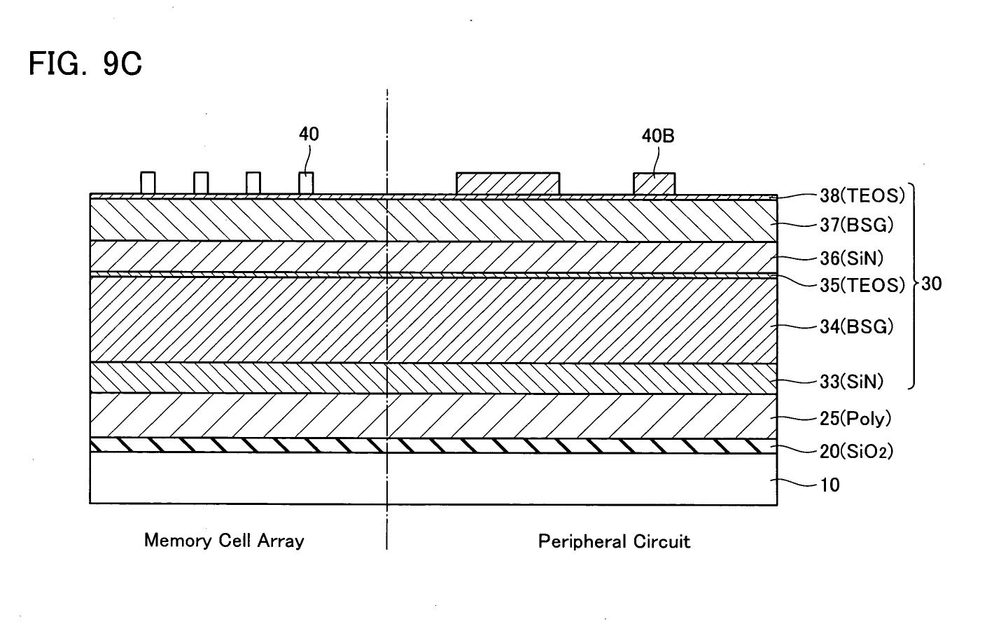

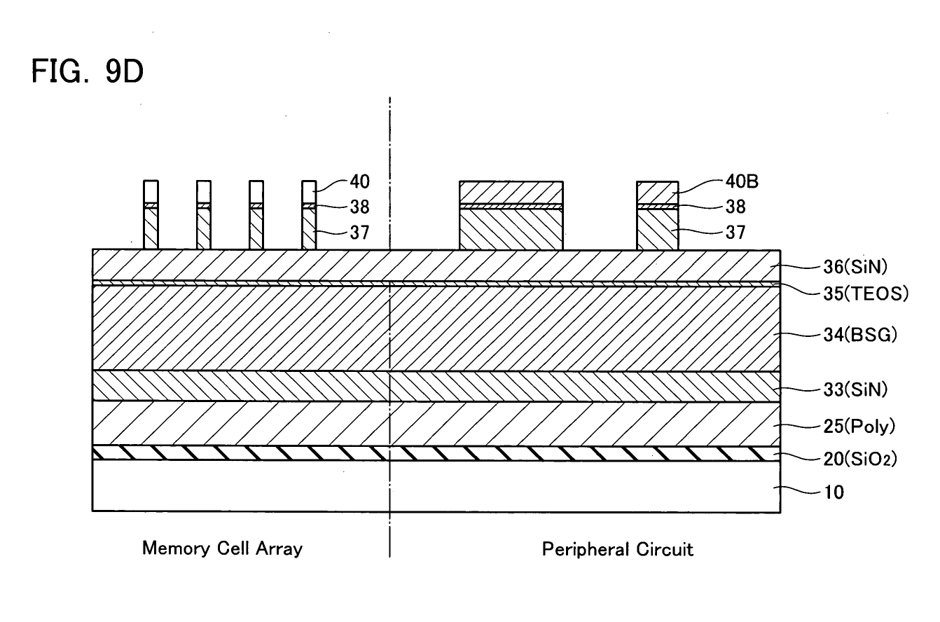

Next, as shown in FIG. 8, a resist 80 is formed only in the memory cell array region. Using the resist 80 as a mask, ions of an impurity (preferably, boron (B), phosphorous (P), arsenic (As) or boron difluoride (BF₂)) are implanted into the second hardmask 40 (40B) present in the peripheral circuit region. In the present embodiment, as described above, the step of ion implantation is implemented prior to patterning the second hard mask 40 in a desired pattern, different from the first embodiment in which ion implantation is implemented after patterning (FIG. 2A). In this case, lithography is implemented in the absence of patterned roughness, different from the first embodiment. Accordingly, lithography can be executed in an ideal situation with less damage to the underlying layer (such as the TEOS film 38). Like in the first embodiment, the ion implantation condition is adjusted such that the hard mask 40B ion-implanted has an impurity concentration of 1×10²⁰ cm⁻³. Subsequent processes include forming a resist 50 having a desired pattern shape in the second hard masks 40, 40B (FIG. 9A), then applying a slimming process (FIG. 9B), almost same as in the first embodiment (FIGS. 1B, 1C).

Subsequent steps (FIGS. 9B-13) are almost same as those in FIGS. 2B-6B. Namely, the resist 50 slimmed as shown in FIG. 9B is subsequently used as a mask to etch the second hard masks 40, 40B by anisotropic etching as shown in FIG. 9C.

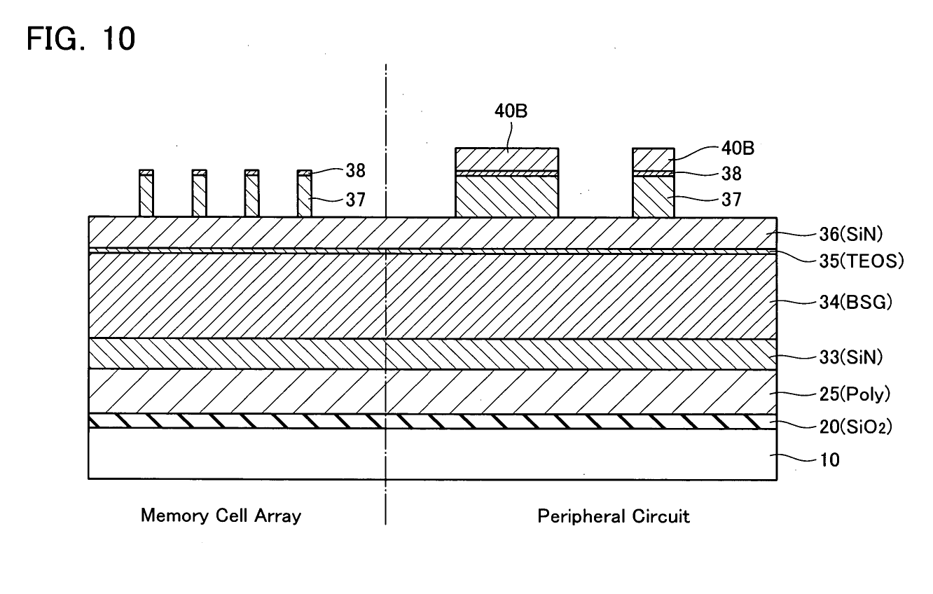

Then, as shown in FIG. 9D, an anisotropic etching with a mask of the second hard masks 40, 40B is applied to etch the sidewall formation film, or the TEOS film 38 and the BSG film 37, of the first hard mask 30. Thereafter, as shown in FIG. 10, a wet etching with an alkaline solution is used to selectively remove the second hard mask 40 not ion-implanted and leave the second hard mask 40B ion-implanted. The wet etching with an alkaline solution has a high selective ratio for the oxide film and the nitride film. Accordingly, it has no ill effect at all on the sidewall formation film, or the TEOS film 38 and the BSG film 37, and the underlying layer, or the silicon nitride film 36. This method can easily remove only the second hard mask 40 in the memory cell array without having any side effect.

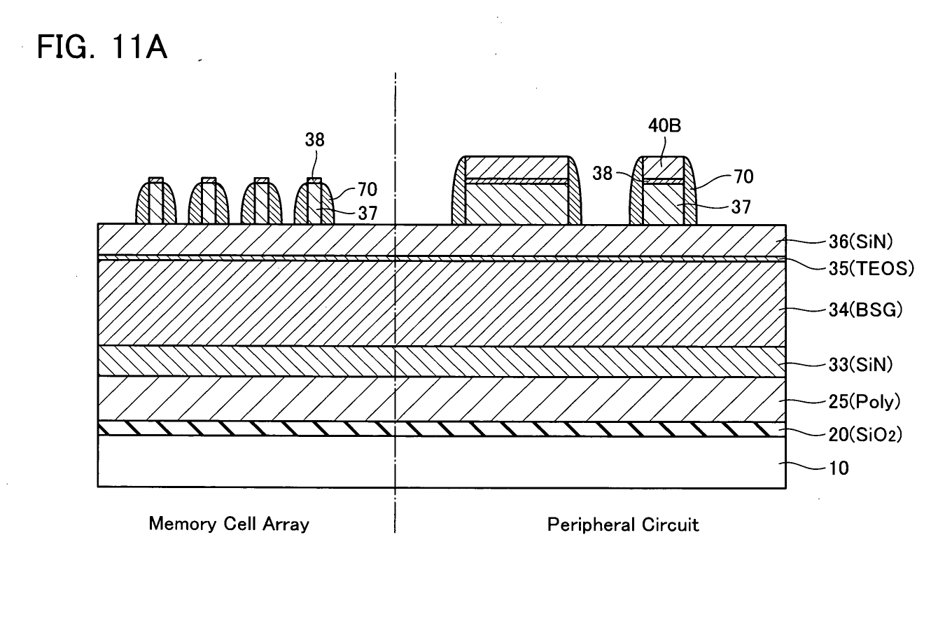

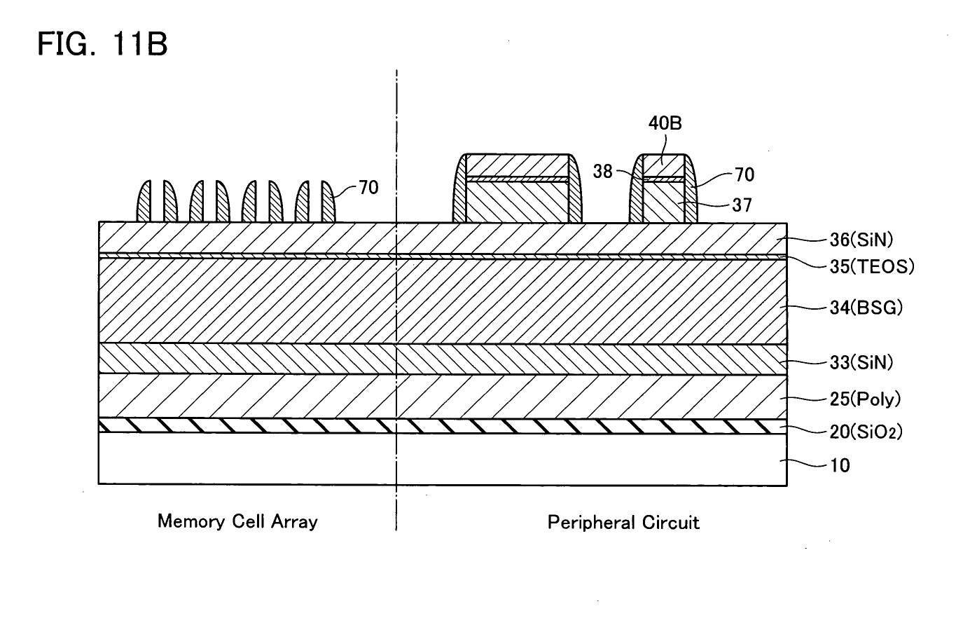

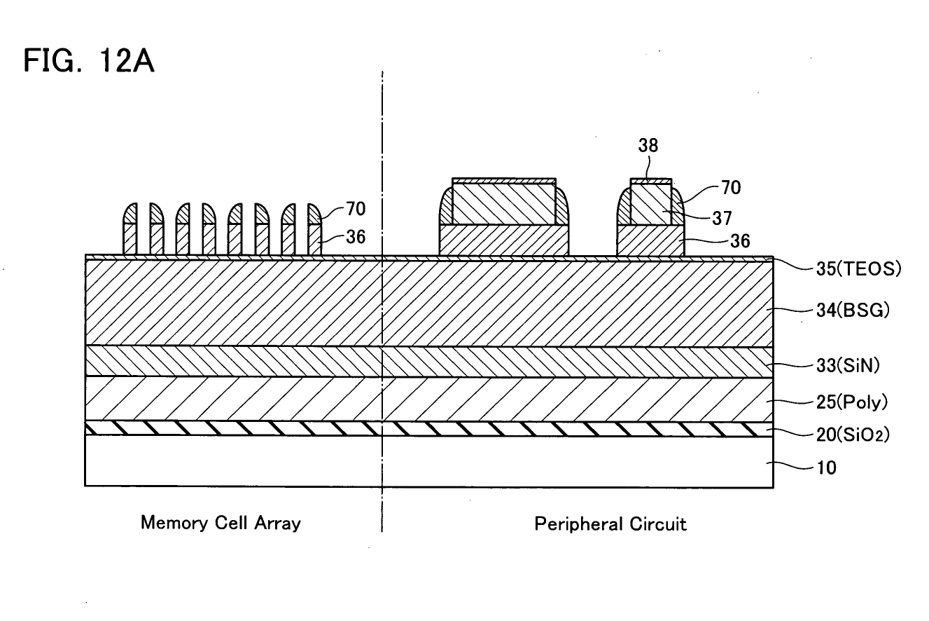

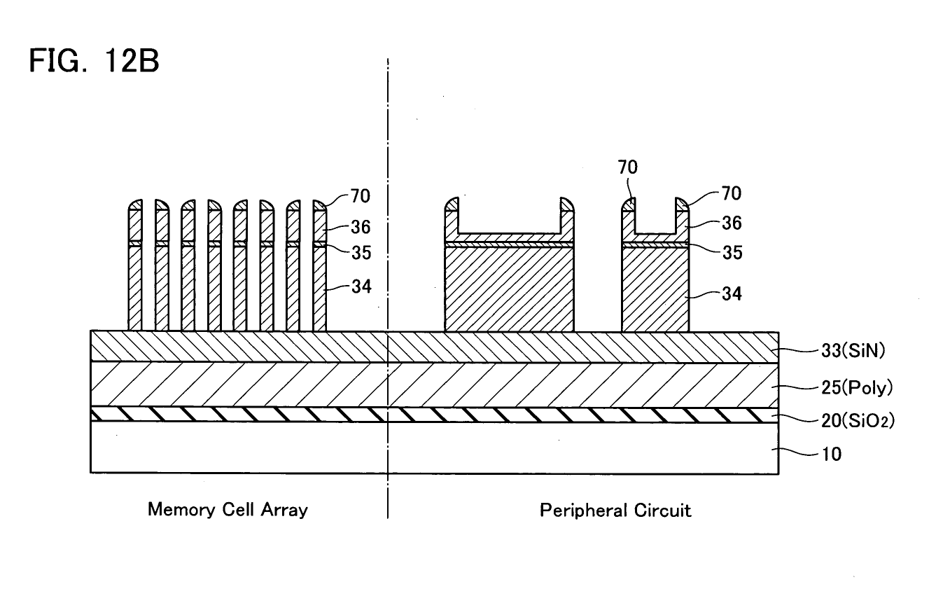

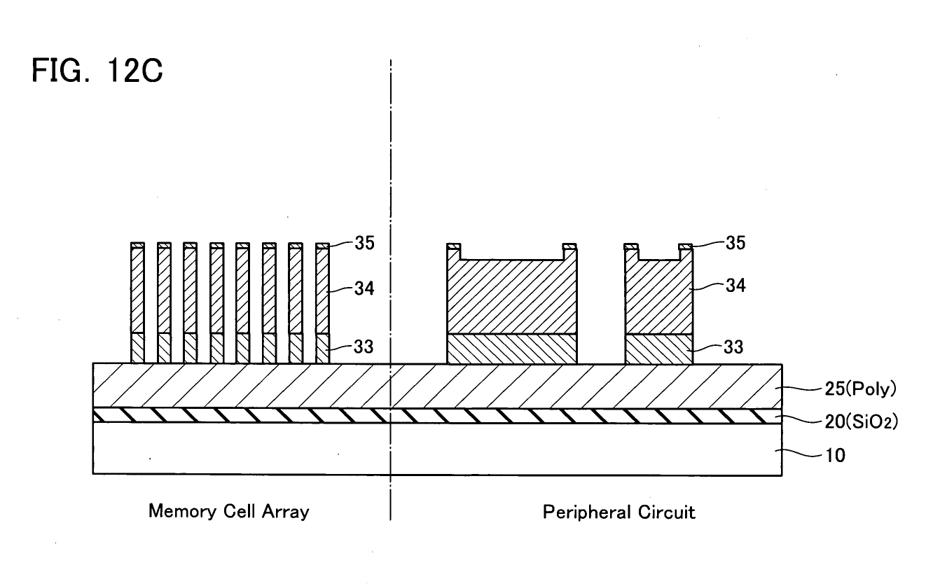

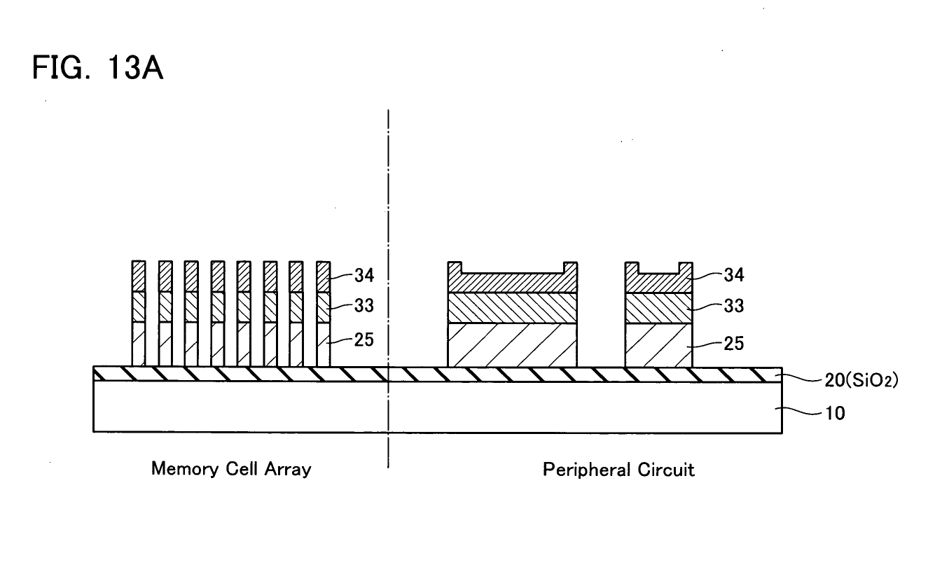

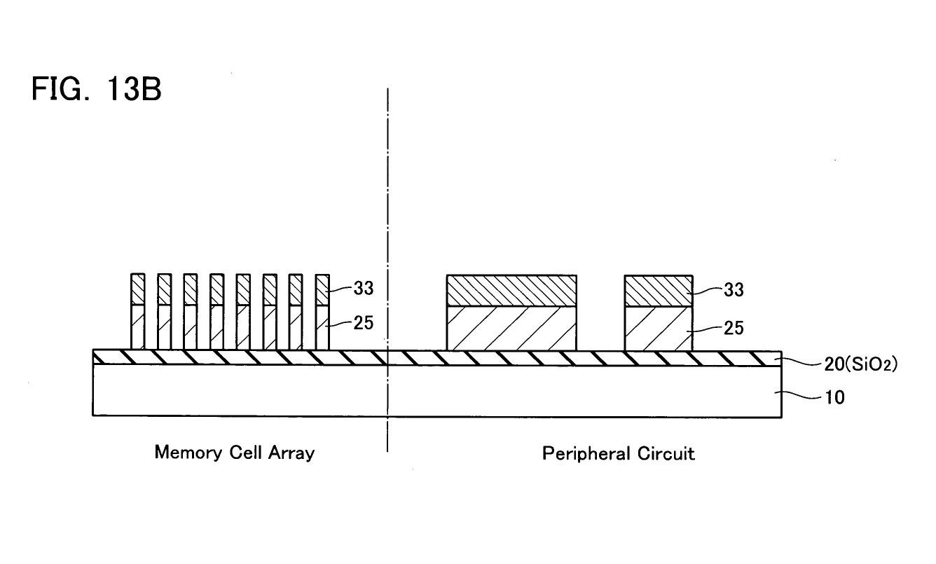

Subsequent processes include forming the sidewall film 70 like the first embodiment (FIG. 11A); etching off the TEOS film 38 and the BSG film 37 sandwiched between portions of the sidewall film 70 in the memory cell array region (FIG. 11B); and then etching the target member or the polysilicon film 25 with a mask of the sidewall film 70 and the first hard mask 30 left (FIGS. 12A-13B). Details of these processes are similar to those in FIGS. 5A-6B of the first embodiment and omitted from the following detailed description. As described, also in the second embodiment, it is possible to form wiring patterns below the resolution limit of lithography and other wiring patterns of any width through an identical lithography. This is effective to reduce the difficulty of lithography particularly over the prior art.

### THIRD EMBODIMENT

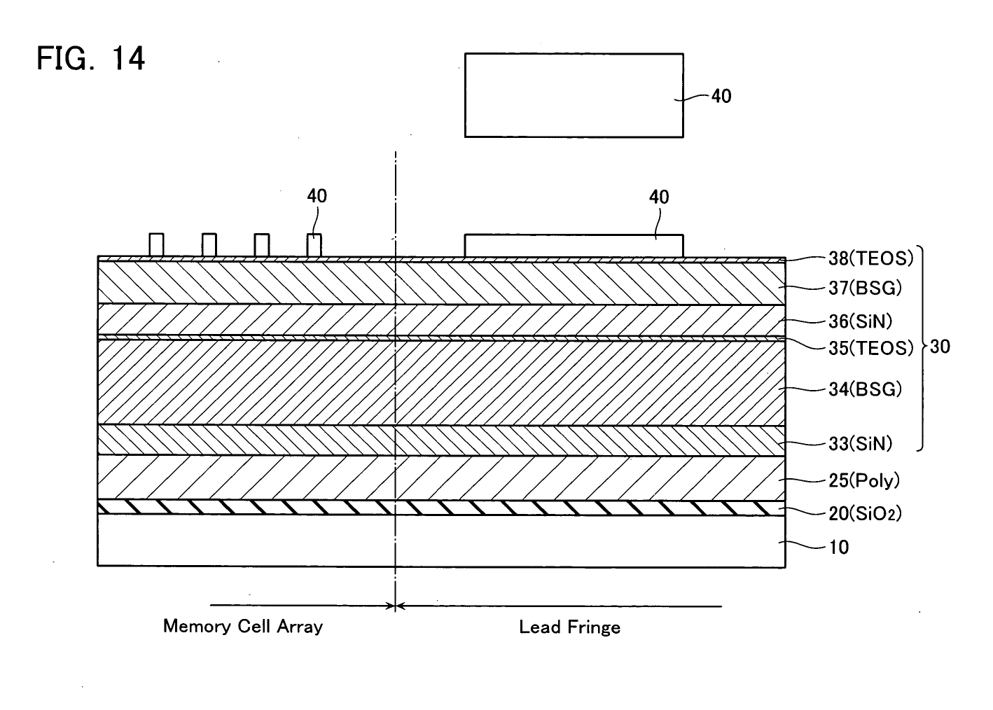

A method of manufacturing semiconductor devices according to a third embodiment of the present invention is described next with reference to FIGS. 14-19B, in which the same components as those in the above embodiments are denoted with the same reference numerals and the duplicated description thereof is omitted hereafter.

Also in this embodiment, the polysilicon film 25 formed on the semiconductor substrate 10 with the silicon oxide film 20 interposed therebetween is etched, like the first embodiment. Then, wiring patterns below the resolution limit of lithography are formed in the memory cell array region. In addition, other wiring patterns of any size or contact fringe regions are formed in the peripheral circuit portion at the same time (the peripheral circuit portion is omitted from the representation in FIGS. 14-19B). In this embodiment, though, wiring patterns of any width directly connected not only to the memory cell array region but also to the memory cell array wiring are formed. The portion of any width directly connected to the memory cell array may be functioned as the contact fringe region of the memory cell array wiring. Namely, in this embodiment, as shown in FIG. 14, a first hard mask 30 is deposited on the target member or the polysilicon film 25. The first hard mask 30 is composed of a silicon nitride film (SiN) 33, a BSG film 34, a TEOS film 35, a silicon nitride film 36, a BSG film 37, and a TEOS film 38, from below. Further, a second hard mask 40 composed of amorphous silicon (or polysilicon) is deposited on the first hard mask 30 and patterned in a desired pattern, followed by a slimming process, like the above-described first embodiment. In the lead fringe region, there is formed a second hard mask 40 of any width, which is not the minimum width W (FIGS. 14-19B show plan views of the second hard mask 40 and others exposed in the surface of the lead fringe region near the upper light corner).

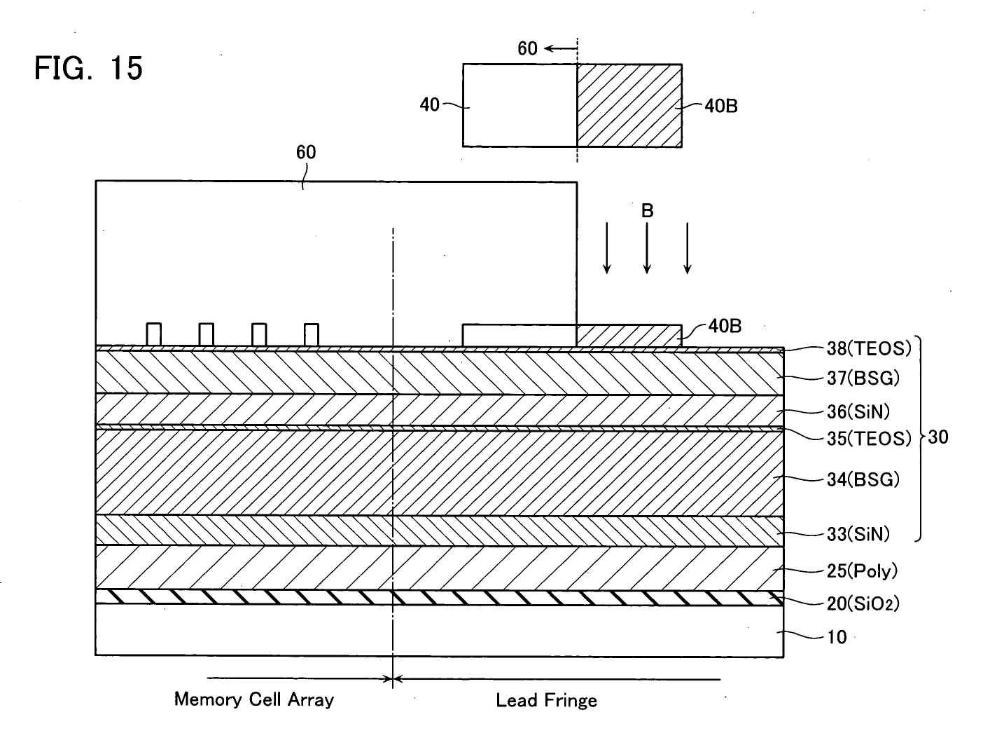

In this embodiment, as shown in FIG. 15, the resist 60 to be turned into a mask at the time of ion implantation is formed not only in the memory cell array region. It is also formed to spread over part of the second hard mask 40 in the lead fringe region. Using the resist 60 as a mask, ions of an impurity (preferably, boron (B), phosphorous (P), arsenic (As) or boron difluoride (BF₂)) are implanted into the second hard mask 40B. Namely, the boundary between the region to be ion-implanted and the region not to be ion-implanted is located in the lead fringe region. In this regard, the present embodiment is different from the other embodiments.

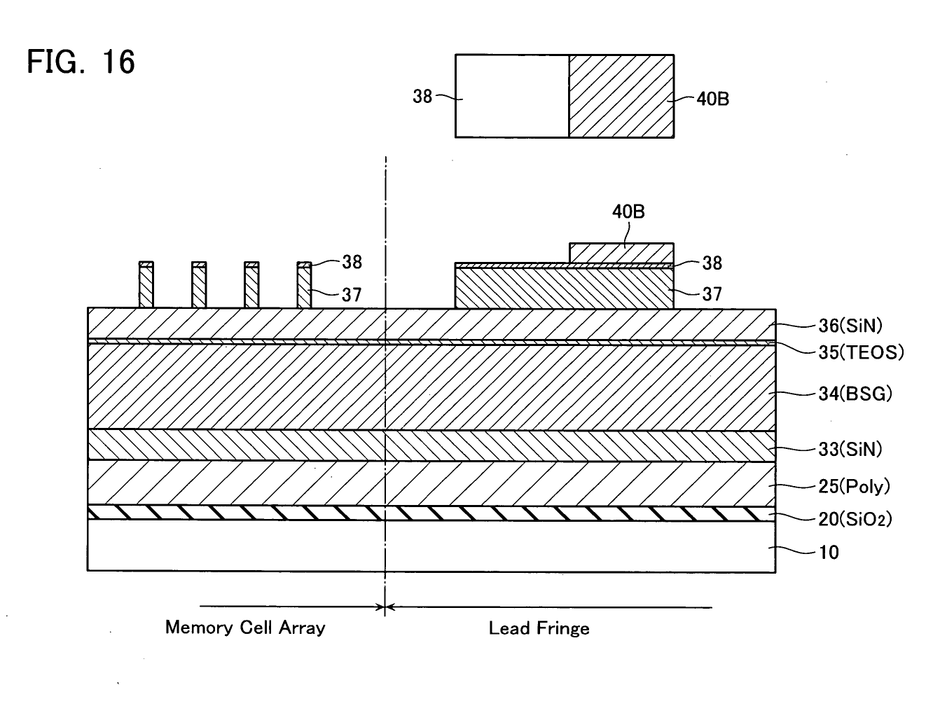

Subsequently, after peeling off the resist 60, as shown in FIG. 16, an anisotropic etching with a mask of the second hard masks 40, 40B is applied to etch the sidewall formation film, or the TEOS film 38 and the BSG film 37, of the first hard mask 30.

Thereafter, a wet etching with an alkaline solution is used to selectively remove the second hard mask 40 not ion-implanted (the memory cell array region and part of the lead fringe region) and leave the second hard mask 40B ion-implanted. The second hard mask 40B remains on part of the TEOS film 38 and the BSG film 37 left in the lead fringe region after etching (the portion on which the resist 60 is not formed) and is etched off from above the other part.

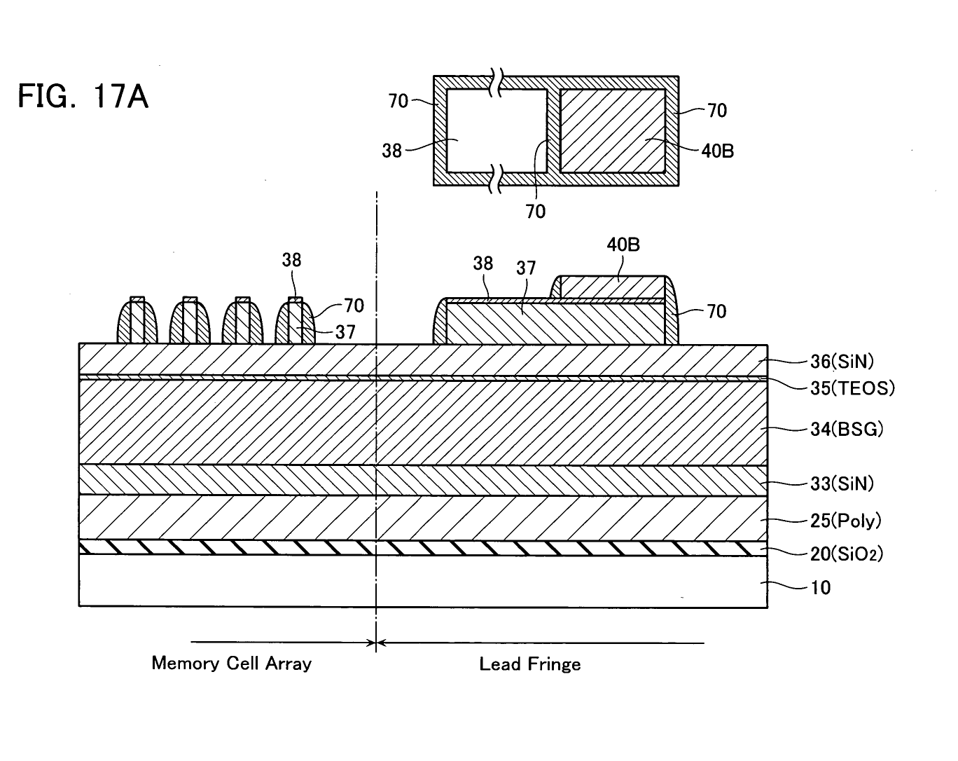

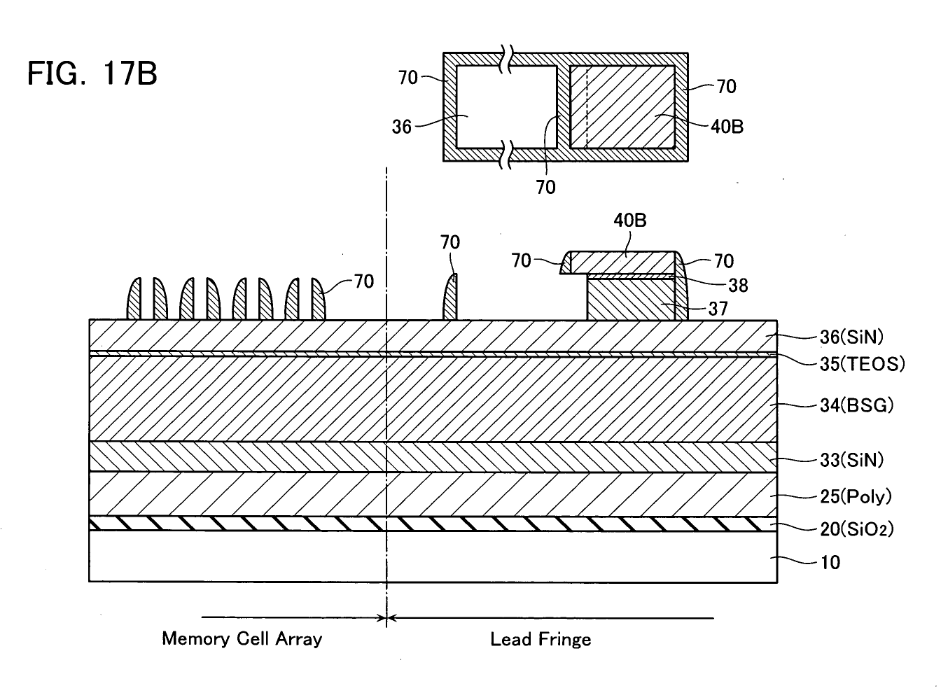

Then, over the entire surface of the first hard mask 30, including sidewalls of the TEOS film 38 and the BSG film 37 etched and the upper surface of the second hard mask 40, an amorphous silicon film is deposited through a CVD process. Then, an anisotropic etching is applied to etch the amorphous silicon film to leave it only on sidewalls of the second hard mask 40B, the TEOS film 38 and the BSG film 37. The film is turned into a sidewall film 70 (amorphous silicon film) as shown in FIG. 17A (that remains in a closed loop shape as shown at the upper right corner in FIG. 17A). The sidewall film 70 is designed to have a width of around ½ W, like the above embodiment.

Thereafter, an anisotropic etching is applied to remove the TEOS film 38 and the BSG film 37 in a state shown in FIG. 17B. In the memory cell array region, like the above embodiment, only the sidewall film 70 remains and serves as a mask for formation of wiring patterns below the resolution limit of lithography (for example, ½ W).

On the other hand, in the lead fringe region, the TEOS film 38 and the BSG film 37 exposed are etched off in a form crawling underneath the second hard mask 40B left (the second hard mask 40B remains in the shape of an “overhang”). The sidewall film 70 formed on the sidewall of the TEOS film 38 and the BSG film 37 etched off remains. This sidewall film serves as a wiring pattern below the resolution limit of lithography in the lead fringe region, which is to be connected to the wiring pattern in the memory cell array region.

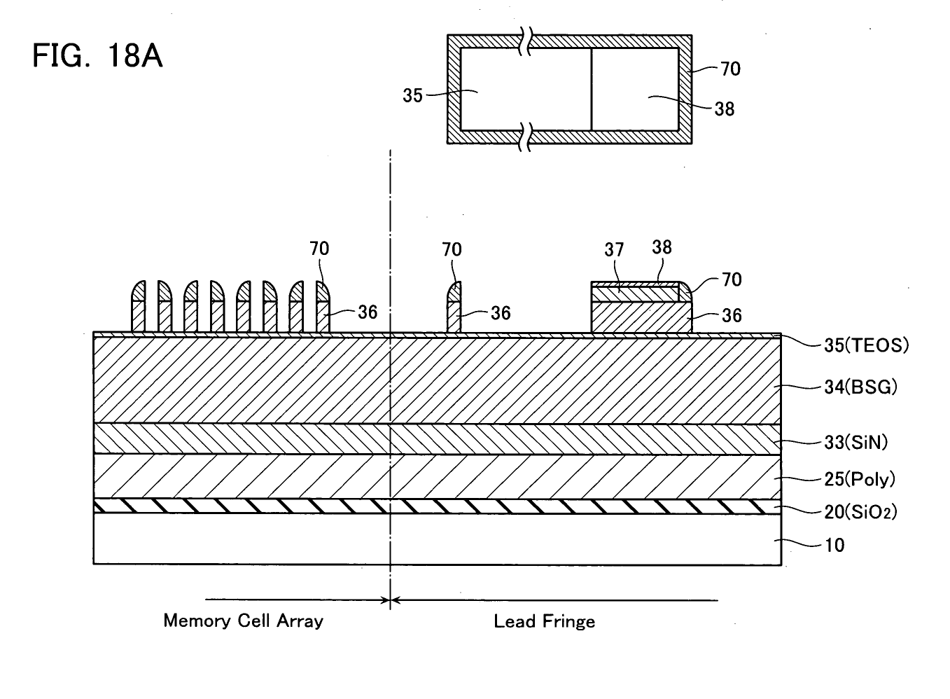

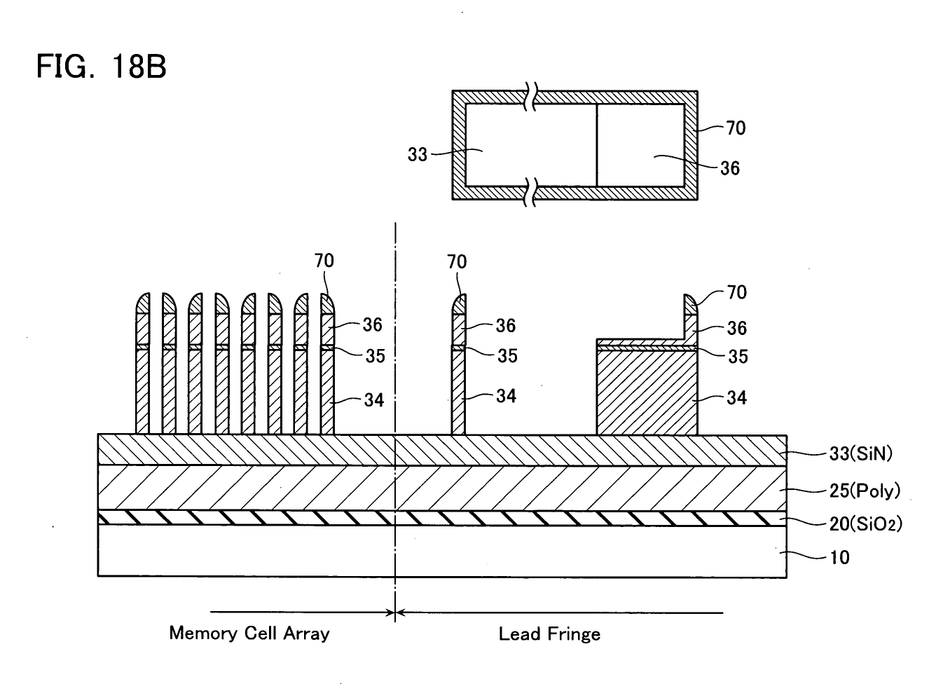

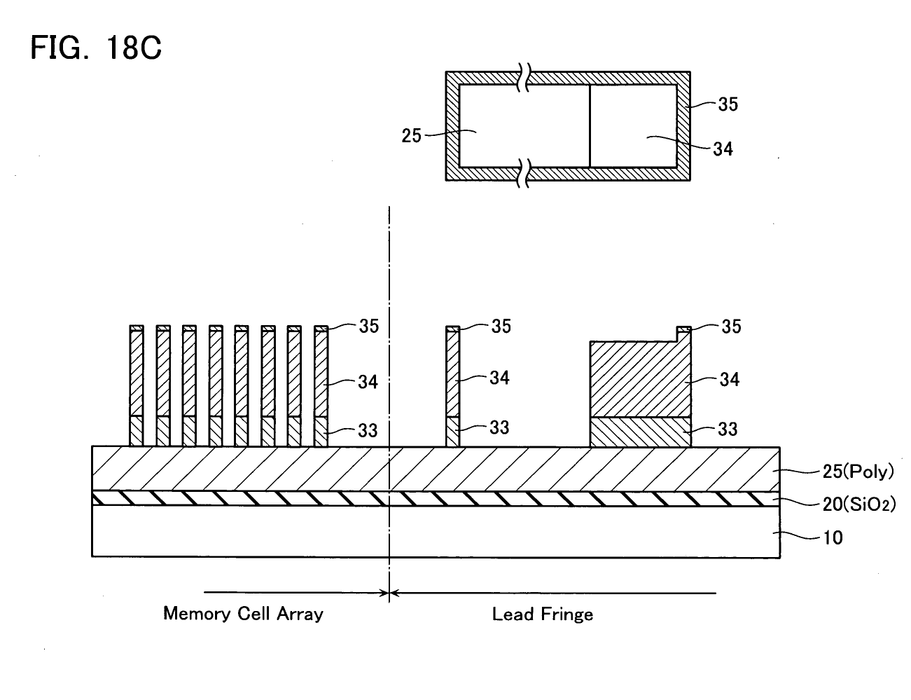

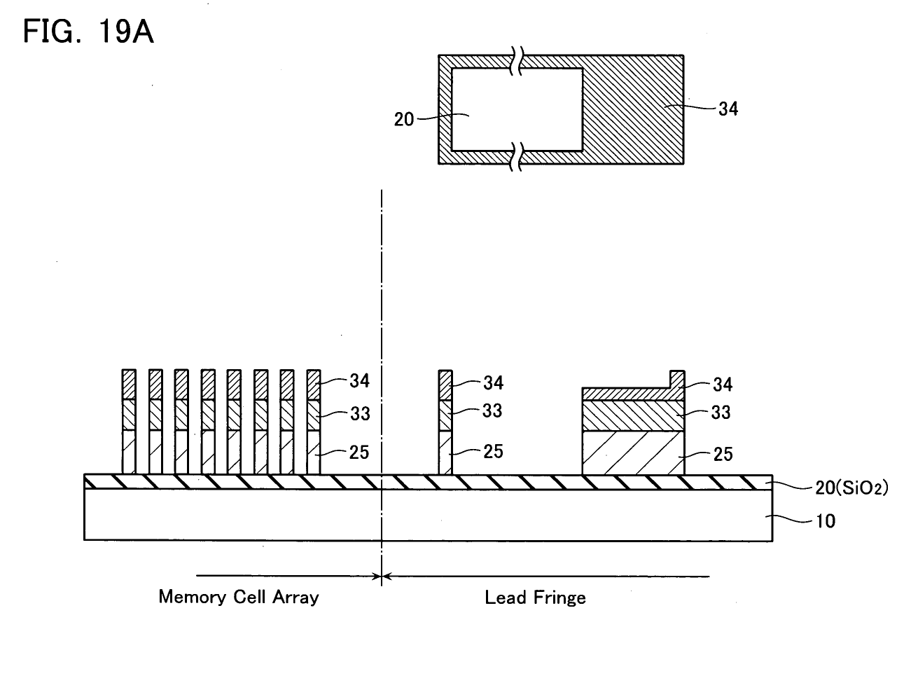

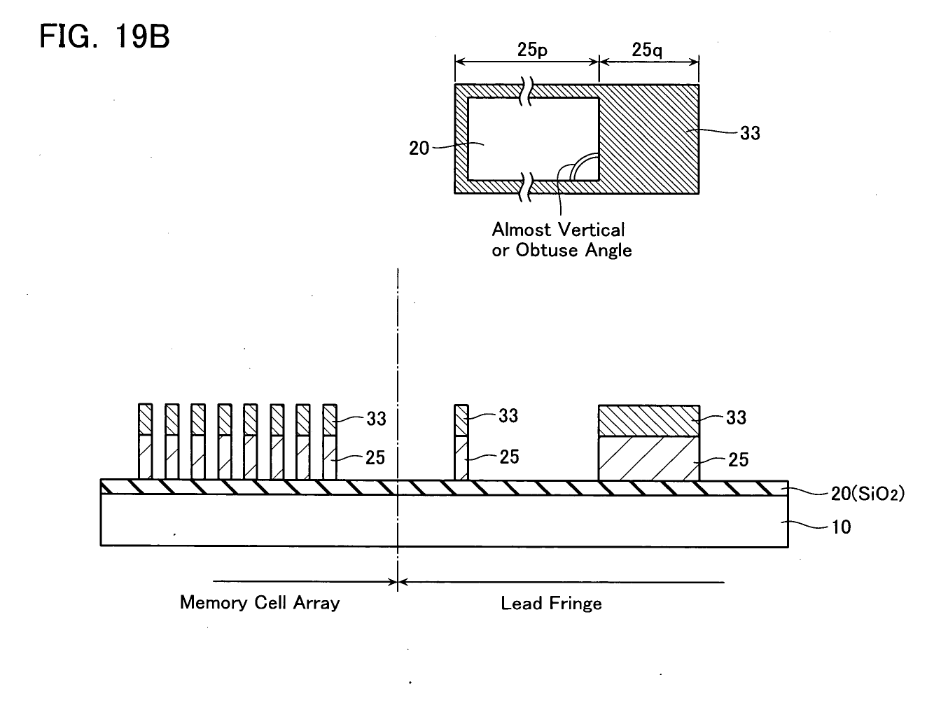

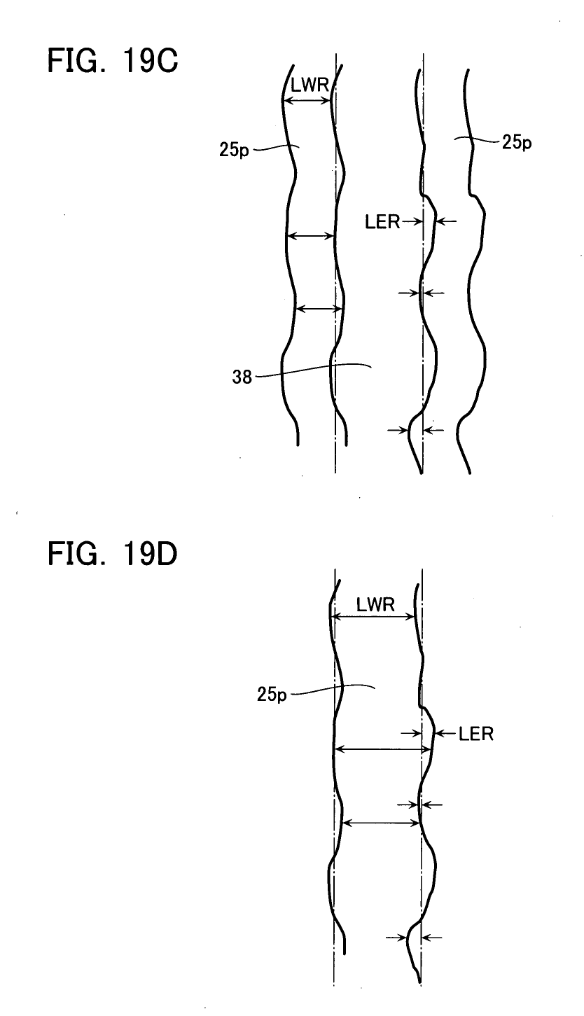

Thereafter, almost same in the first embodiment, the TEOS film 38, the BSG film 37 and the sidewall film 70 etched are used as a mask to etch the polysilicon film 25 as shown in FIGS. 18A-19B to form wiring patterns. In the memory cell array region, wiring patterns below the resolution limit of lithography are formed. On the other hand, in the lead fringe region, a wiring pattern 25a below the resolution limit of lithography and another wider wiring pattern of any width (wider section 25q) are formed as shown at the upper right corner in FIG. 19B. Namely, the wider section 25q is formed as derived from the second hard mask 40B left and the surrounding sidewall film 70 while the wiring pattern 25p below the resolution limit of lithography is formed as derived only from the sidewall film 70. The wiring pattern 25p is successively connected to the wider section 25q.

The wiring pattern 25p and the wider section 25q formed through the method of the present embodiment have the following three characteristics geometrically.

The first characteristic lies in the fact that the edge of the wider section 25q and the edge of the wiring pattern 25p intersect almost vertical or at an obtuse angle on the inner circumference of the closed-loop shape. This is because the wider section 25q is defined by the ion implantation in accordance with the large mask as shown in FIG. 15. The wiring pattern 25p and the wider section 25q as shown in FIG. 19A may be formed through the sidewall transfer process for forming the wiring pattern 25p and the photolithography aligned with the position of the wiring pattern 25p for forming the wider section 25q. In this case, the distortion of the resist on development causes the edge of the wider section 25q and the edge of the wiring pattern 25p to intersect at an acute angle on the inner circumference, different from the present embodiment.

The second characteristic lies in the fact that the straight line on the outer circumference along the closed-loop shape of the wiring pattern 25p is formed aligned with the straight line on the outer circumference of the wider section 25q in the form of almost the same straight line. This is because the wider section 25q is formed as derived from the second hard mask 40B and the surrounding sidewall film 70.

The third characteristic lies in the fact that the line edge roughness (LER) is larger than the line width roughness (LWR) in the wiring layer 25p (LER>LWR) (see FIG. 19C). When the sidewall transfer process is applied to form the wiring pattern 25p, the hard mask to which the sidewall film is transferred has a relation of LWR>LER. This is because the sidewall film 70 formed on the sidewall of the hard mask results in wiring of an almost constant width as only the film thickness of the sidewall material deposited determines the roughness. In contrast, when the general photolithography is used to form a wiring pattern, the resist-caused edge position roughness occurs independently on edges at both left and right sides of the wiring pattern 25p, resulting in LWR>LER (see FIG. 19D). The third characteristic is not limited to the present embodiment but can be observed in the wiring pattern formed in accordance with the sidewall film through the sidewall transfer process in general.

### FOURTH EMBODIMENT

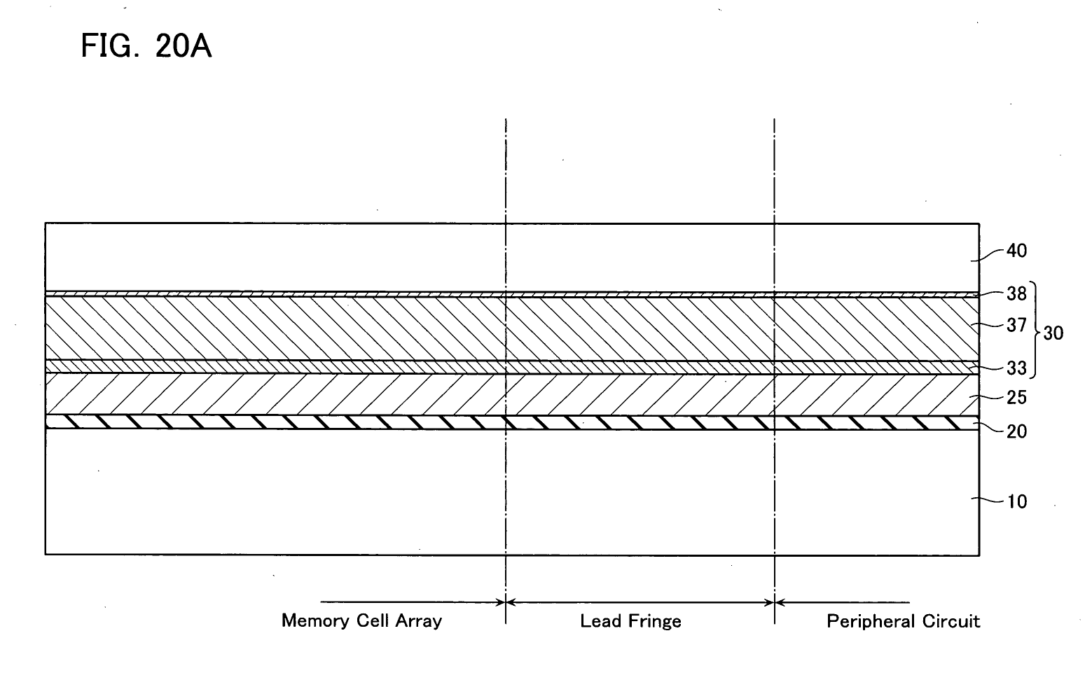

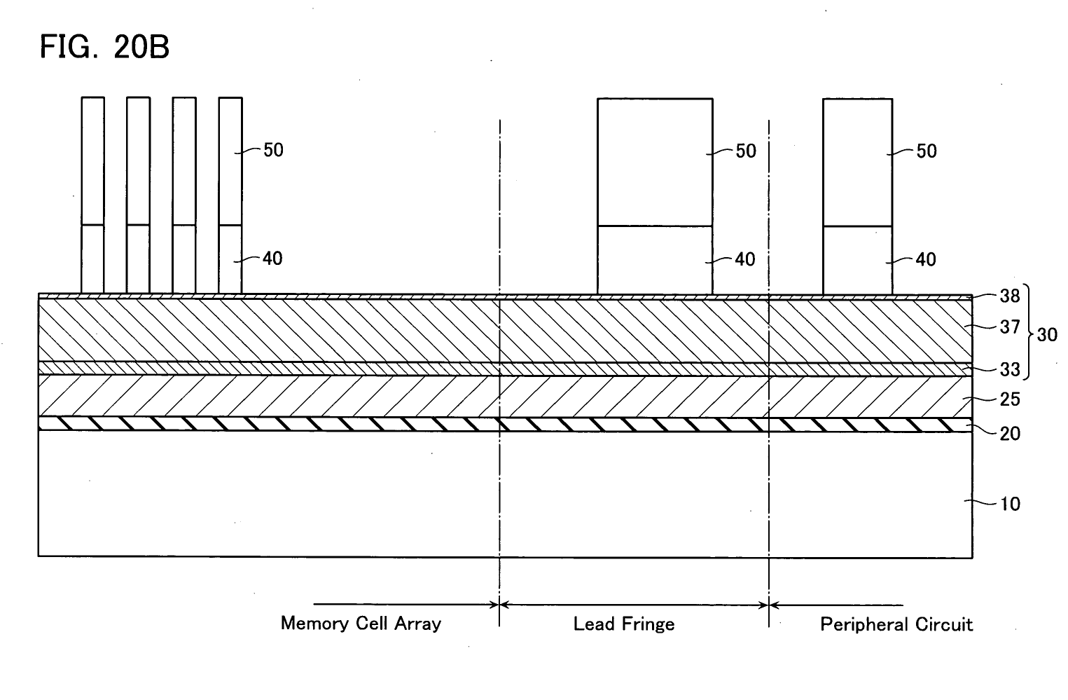

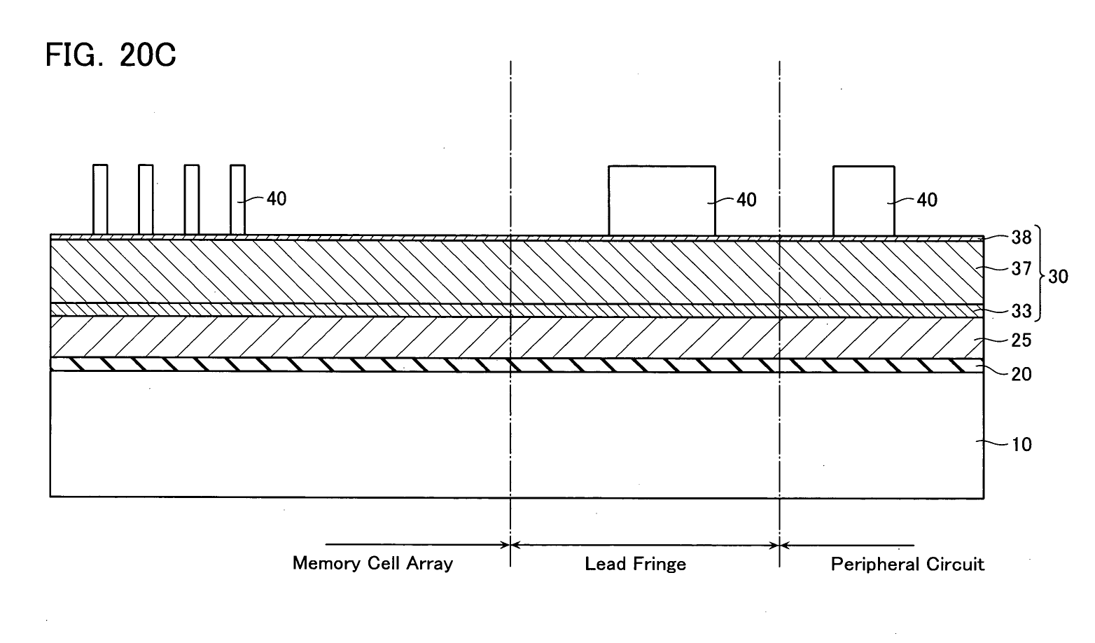

A method of manufacturing semiconductor devices according to a fourth embodiment of the present invention is described next with reference to FIGS. 20A-25C, in which the same components as those in the above embodiments are denoted with the same reference numerals and the duplicated description thereof is omitted hereafter.

In the first through third embodiments, on the sidewall of the first hard mask 30 (specifically, the sidewall formation film, or the TEOS film 38 and the BSG film 37) etched with the second hard mask 40, the sidewall film 70 composed of amorphous silicon is formed. On the contrary, in the present embodiment, a sidewall film 70A composed of silicon nitride is formed on the sidewall of the second hard mask 40 instead of the sidewall of the first hard mask 30. This sidewall film 70A is used to form wiring patterns below the resolution limit of lithography. A method of manufacturing the same is described below with reference to the drawings.

First, as shown in FIG. 20A, a target member or a polysilicon film 25 is formed on a semiconductor substrate 10 with a silicon oxide film 20 interposed therebetween. A three-layered first hard mask 30 composed of a silicon nitride film 33, a BSG film 37, and a TEOS film 38 is formed thereon. A second hard mask 40 composed of amorphous silicon (or polysilicon) is formed on the first hard mask 30.

Next, as shown in FIG. 20B, a resist 50 is formed on the second hard mask 40 and used as a mask to etch the second hard mask 40. In the lead fringe region, a lead fringe includes a wider contact fringe, and a wiring pattern coupled thereto, which is below the resolution limit of lithography (and connected to the memory cell array region).

Then, as shown in FIG. 20C, the second hard mask 40 formed is subjected to a slimming process. Instead of subjecting the second hard mask 40 to the slimming process, the resist 50 may be subjected to the slimming process, like the above embodiment.

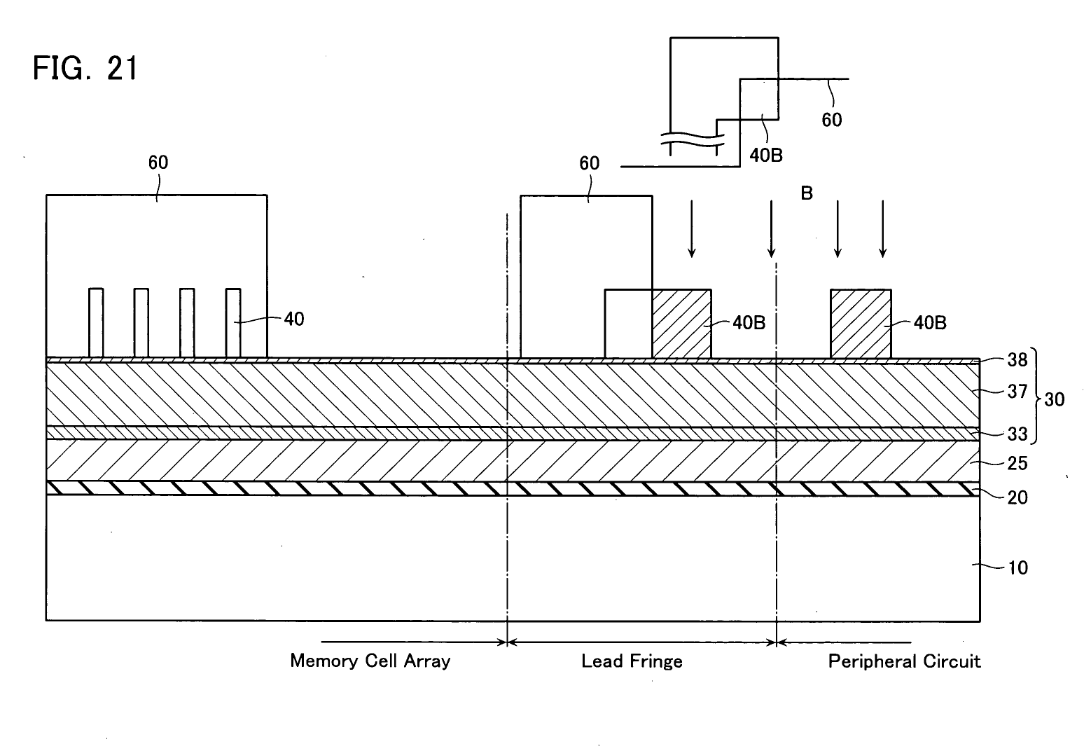

After the slimming process, as shown in FIG. 21, a resist 60 is formed over the region intended to form a wiring pattern therein, which is below the resolution limit of lithography. This resist is used as a mask to implant ions of an impurity (preferably, boron (B), phosphorous (P), arsenic (As) or boron difluoride (BF₂)) into the second hard mask 40B present in other portions. In the peripheral circuit region and the lead fringe formation region, as shown in a plan view at the upper right corner of FIG. 21, the resist 60 is formed with an aperture that extends over part of the lead fringe region and the peripheral circuit region. This enables impurity ions to be implanted into only part of the lead fringe region and the second hard mask 40B in the peripheral circuit region.

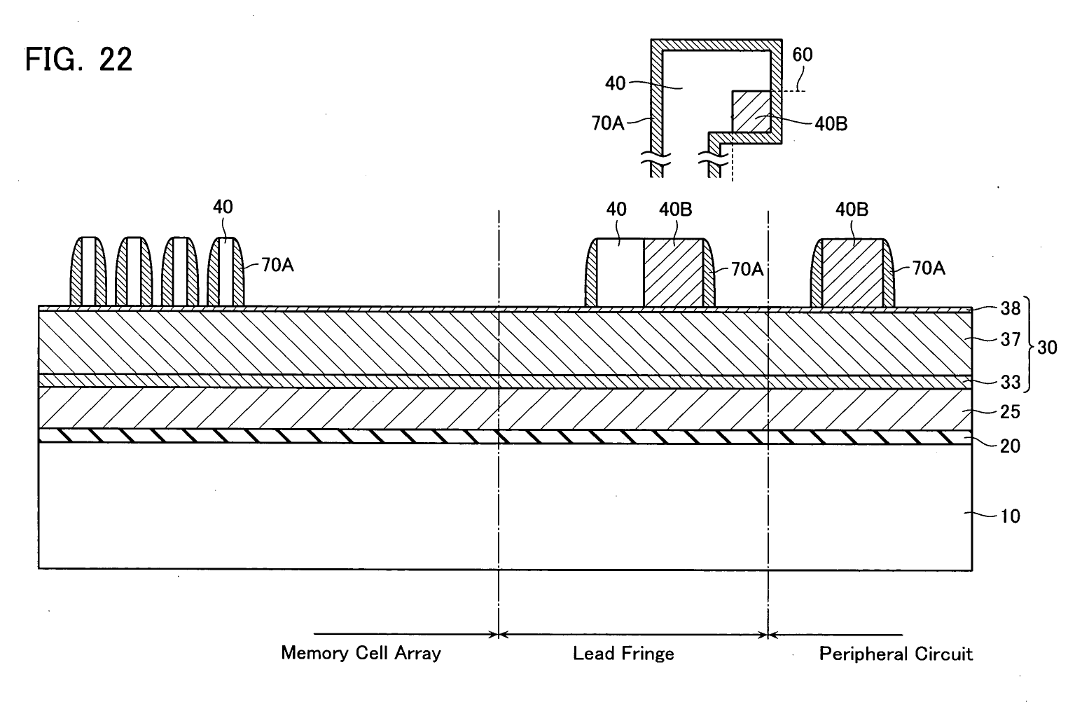

Next, as shown in FIG. 22, after peeling off the resist 60, a sidewall film 70A composed of silicon nitride is formed on the sidewalls of the second hard masks 40, 40B. In the above embodiment, the sidewall film 70 is manufactured of amorphous silicon. On the contrary, in this embodiment, the sidewall film 70A is formed on the second hardmask composed of amorphous silicon. Therefore, the sidewall film 70A is composed of silicon nitride, which has a higher selective ratio for amorphous silicon in wet etching with an alkaline solution.

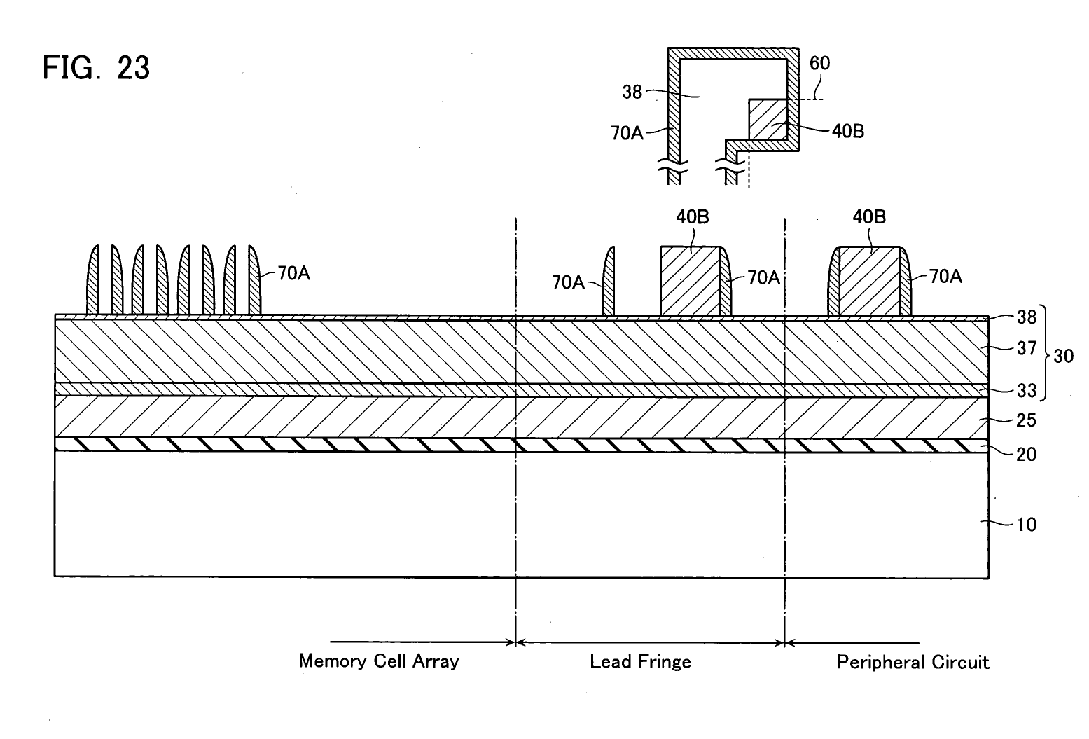

Subsequently, as shown in FIG. 23, a wet etching with an alkaline solution is used to selectively remove the second hard mask 40 not ion-implanted and leave the second hard mask 40B ion-implanted. The wet etching with an alkaline solution has a high selective ratio for the oxide film and the nitride film. Accordingly, it has no ill effect at all on the sidewall film 70A and the underlying layer or the TEOS 38. In the memory cell array region, like the above embodiment, the sidewall film 70A remains with a line width and a space width of ½ W and allows wiring patterns to be formed below the resolution limit of lithography. On the other hand, in the peripheral circuit region, thick wiring patterns of any width can be formed. In contrast, in the lead fringe region, wiring patterns to be formed below the resolution limit of lithography, and thick wiring patterns of any width connected thereto can be formed. The thick wiring pattern can be employed as a contact fringe of a fine wiring pattern.

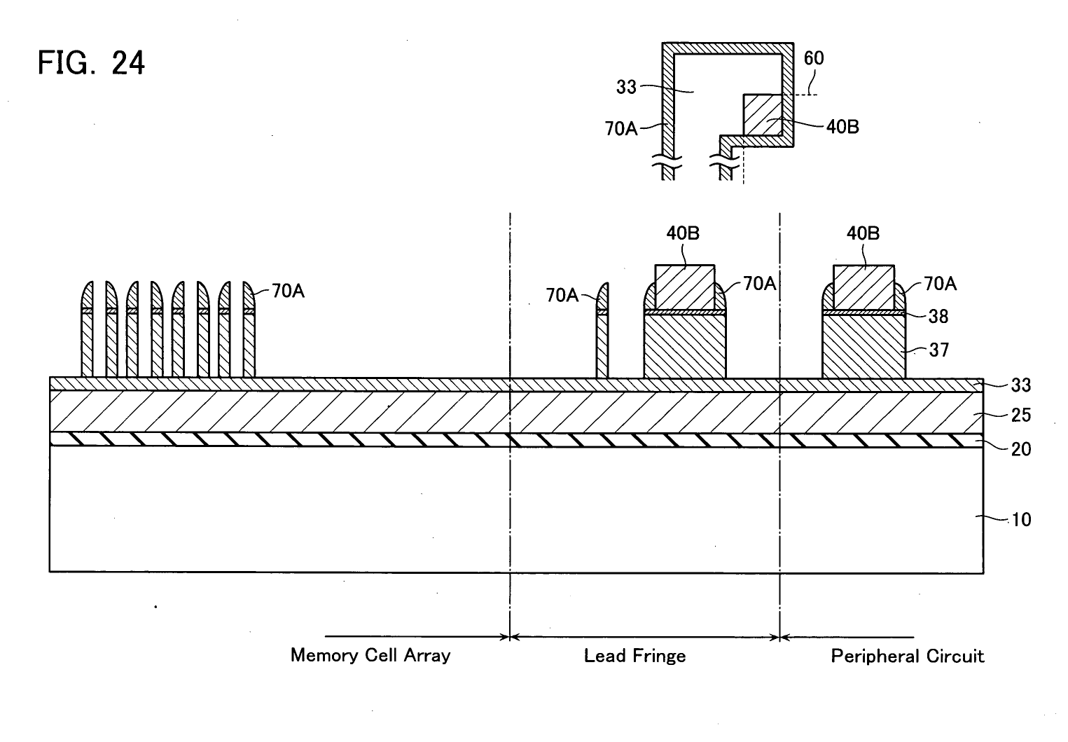

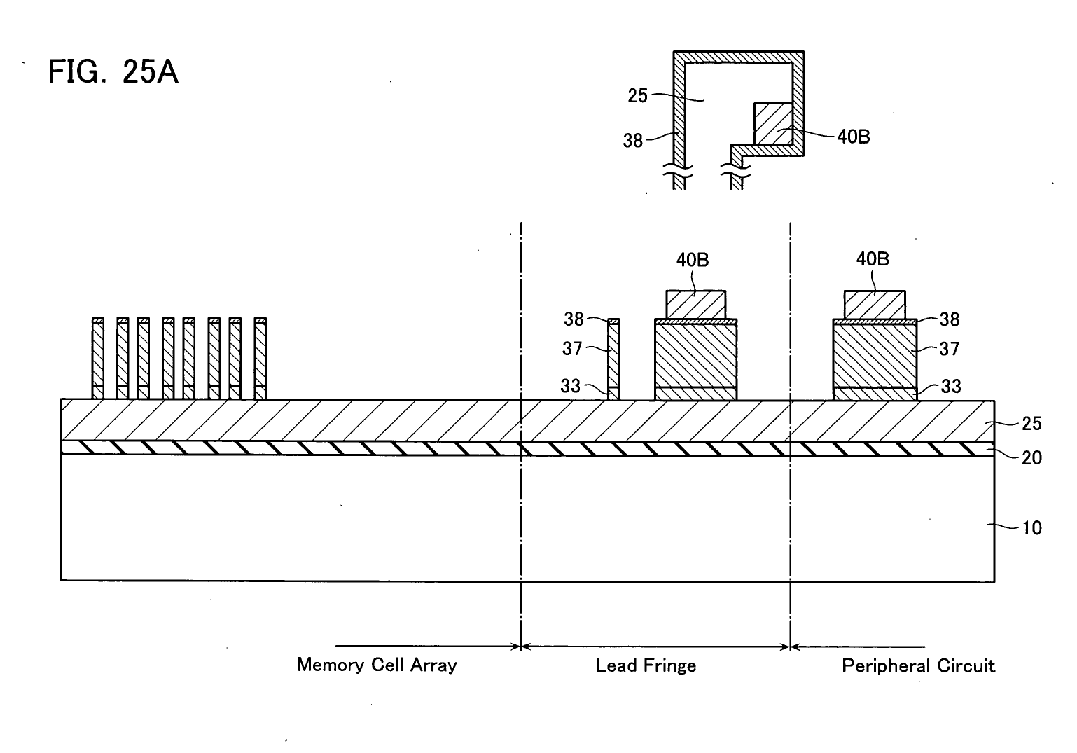

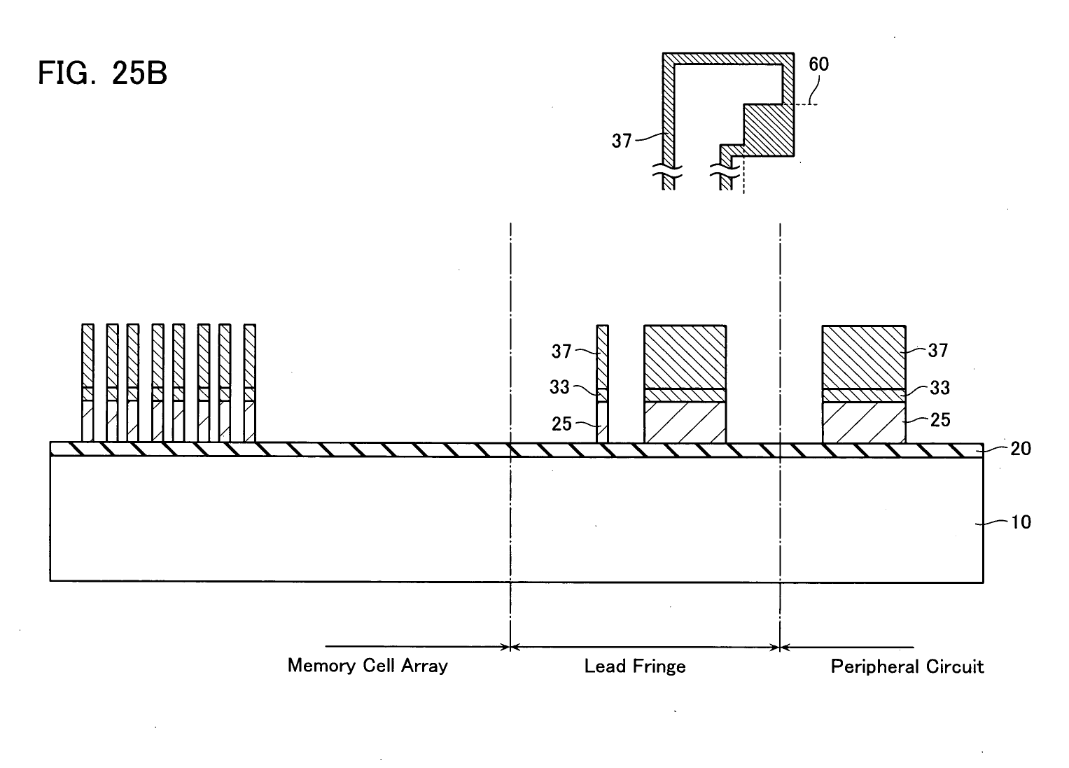

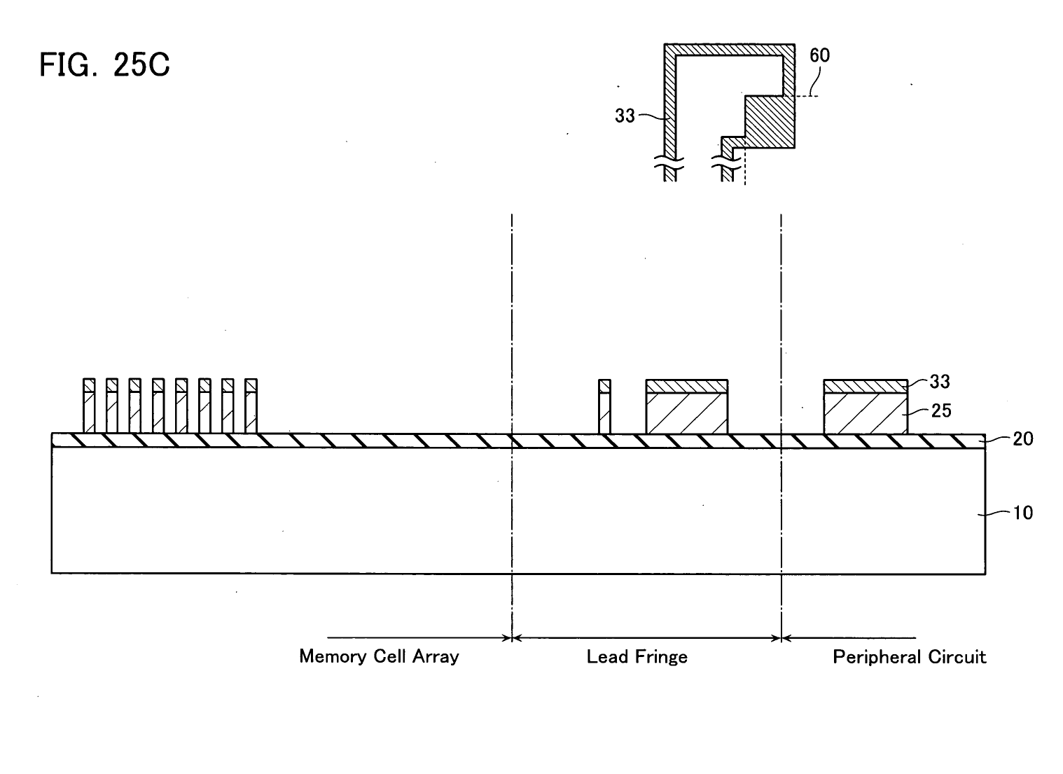

Thereafter, as shown in FIG. 24, the second hard mask 40B and the sidewall film 70A left are used as a mask to etch the TEOS film 38 and the BSG film 37. Subsequently, as shown in FIG. 25A, the underlying silicon nitride film 34 is etched off together with the sidewall film 70A. Further, the first hard mask 30 left is used as a mask to etch the target member or the polysilicon film 25 as shown in FIG. 25B. Finally, as shown in FIG. 25C, a HF vapor treatment or the like is applied to etch only the BSG film 34 under the condition with a high selective ratio for the silicon oxide 20. As a result, a wiring layer composed of the polysilicon film 25 is formed with the cap layer of the silicon nitride film 33 thereon.

The embodiments of the invention have been described above though the present invention is not limited to these embodiments but rather can be given various modifications and additions without departing from the scope of the invention. For example, in the above embodiments, the sidewall films 70, 70A are formed of amorphous silicon or silicon nitride though other materials such as silicon oxide may be employed depending on the etching condition and so forth.

What is claimed is:

1. A method of manufacturing semiconductor devices, comprising:
forming a first hard mask on a target member to be etched;
forming a second hard mask on said first hard mask;
implanting ions into a portion of said second hard mask for modification to vary the etch rate for wet etching in comparison with a portion not ion-implanted;
etching said first hard mask with a mask of said second hard mask;
selectively etching off only said portion not ion-implanted of said second hard mask by wet etching;
forming a sidewall film on sidewalls of said first hard mask;
selectively etching off said first hard mask having an upper portion exposed, not covered with said second hard mask; and
etching off said target member with a mask of said sidewall film and said first hard mask.

2. The method of manufacturing semiconductor devices according to claim 1, wherein said sidewall film is also formed on sidewalls of said second hard mask left, not etched in the step of etching off.

3. The method of manufacturing semiconductor devices according to claim 1, wherein the step of implanting ions includes patterning said second hard mask and then forming a mask on a portion other than said portion.

4. The method of manufacturing semiconductor devices according to claim 1, wherein said second hard mask is composed of amorphous silicon or polysilicon.

5. The method of manufacturing semiconductor devices according to claim 4, wherein impurity ions for use in said implanting ions are of boron (B), phosphorous (P), arsenic (As) or boron difluoride (BF₂).

6. The method of manufacturing semiconductor devices according to claim 1, wherein said first hard mask is formed of a silicon nitride film (SiN), a BSG film, a TEOS film, a silicon nitride film, a BSG film, and a TEOS film, deposited from below.

7. The method of manufacturing semiconductor devices according to claim 6, wherein said sidewall film is composed of amorphous silicon.

8. The method of manufacturing semiconductor devices according to claim 1, wherein said first hard mask has a higher selective ratio for said second hard mask in wet etching with an alkaline solution.

9. The method of manufacturing semiconductor devices according to claim 1, wherein said first hard mask is formed of a silicon nitride film (SiN), a BSG film, a TEOS film, a silicon nitride film, a BSG film, and a TEOS film, deposited from below,
wherein said second hard mask is composed of amorphous silicon or polysilicon.

10. The method of manufacturing semiconductor devices according to claim 9, wherein said sidewall film is composed of amorphous silicon.

11. The method of manufacturing semiconductor devices according to claim 1, further comprising:
forming on said second hard mask a resist having a line-and-space of the minimum line width that is a resolution limit of lithography;
slimming said resist to a width below said resolution limit of lithography; and
applying an anisotropic etching to said second hard mask with a mask of said fine-patterned resist.

12. A method of manufacturing semiconductor devices, comprising:
forming a first hard mask on a target member to be etched;
forming a second hard mask on said first hard mask;
implanting ions into a portion of said second hard mask for modification to vary the etch rate for wet etching in comparison with a portion not ion-implanted;
forming a sidewall film on sidewalls of said second hard mask;
selectively etching off only said second hard mask not ion-implanted by wet etching;
etching said first hard mask with a mask of said second hard mask and said sidewall film;
etching off said target member with a mask of said first hard mask.

13. The method of manufacturing semiconductor devices according to claim 12, wherein said second hard mask is composed of amorphous silicon or polysilicon.

14. The method of manufacturing semiconductor devices according to claim 13, wherein impurity ions for use in said implanting ions are of boron (B) phosphorous (P), arsenic (As) or boron difluoride (BF₂).

15. The method of manufacturing semiconductor devices according to claim 13, wherein said sidewall film is a silicon nitride film.

16. The method of manufacturing semiconductor devices according to claim 12, wherein said sidewall film has a higher selective ratio for said second hard mask in wet etching with an alkaline solution.

17. The method of manufacturing semiconductor devices according to claim 12, further comprising:
forming on said second hard mask a resist having a line-and-space of the minimum line width that is a resolution limit of lithography;
slimming said resist to a width below said resolution limit of lithography; and
applying an anisotropic etching to said second hard mask with a mask of said fine-patterned resist.

18. A semiconductor device, comprising a wiring layer, said wiring layer provided by forming a sidewall film in a closed-loop shape along a sidewall of a hard mask, implanting ions into a portion of said hard mask with a mask, then etching off said hard mask except for said portion, and etching a target member to be etched with a mask of said portion and said sidewall film,
wherein said wiring layer includes a wider section formed as derived from said portion and said sidewall film, and a wiring section formed as derived only from said sidewall film,
wherein the line edge roughness is larger than the line width roughness in said wiring layer,
wherein the edge of said wider section and the edge of said wiring section intersect vertical or at an obtuse angle on the inner circumference of said closed-loop shape,
wherein the outer circumference of said wiring section along said closed-loop shape is formed in the form of the same straight line, including the proximity of the boundary around said portion.
